(19) United States
(12) Patent Application Publication
(10) Pub. No.: US 2026/0251969 A1
(43) Pub. Date: Aug. 27, 2026

(54) RADIATION-SENSITIVE RESIST COMPOSITION AND PATTERN FORMATION METHOD USING THE SAME

(71) Applicant: Samsung Electronics Co., Ltd., Suwon-Si (KR)

(72) Inventors: Yoshinobu KAMAKURA, Yokohama (JP); Taro MIYOSHI, Yokohama (JP); Nobuji SAKAI, Yokohama (JP); Hideomi YAMAGA, Yokohama (JP); Tadao YAGI, Yokohama (JP)

(73) Assignee: Samsung Electronics Co., Ltd., Suwon-si (KR)

(21) Appl. No.: 19/456,526

(22) Filed: Jan. 22, 2026

(30) Foreign Application Priority Data
Feb. 26, 2025 (JP) 2025-029166
Sep. 5, 2025 (KR) 10-2025-0126884

(51) Int. Cl. G03F 7/004; G03F 7/039

(52) U.S. Cl. CPC G03F 7/0042; G03F 7/0048; G03F 7/039

(57) ABSTRACT

A radiation-sensitive resist composition including an ionic salt (A); and a solvent (B). The ionic salt (A) including an ion (a) and a counter ion (b); the ion (a) having a metal chalcogenide cluster structure; and the counter ion (b) having a charge counter to a charge of the ion (a). The ion (a) including a halogen atom and at least one metal atom selected from Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, or Bi.

### CROSS-REFERENCE TO RELATED APPLICATION

This application claims the benefit of Japanese Patent Application No. 2025-029166, filed on Feb. 26, 2025, in the Japanese Patent Office and Korean Patent Application No. 10-2025-0126884, filed on Sep. 5, 2025, in the Korean Intellectual Property Office, the disclosures of which are incorporated herein in their entireties by reference.

### BACKGROUND

The disclosure relates to a radiation-sensitive resist composition and a pattern formation method using the same.

Research and development of lithography technology is underway in order to satisfy the increasing demand for miniaturization of semiconductor processing, which enables higher speeds and lower power consumption of semiconductor chips. Recently, light sources for lithography have shifted to extreme ultraviolet (EUV) sources, which may be used to create resist patterns with a line width of about 20 nm. Chemically amplified resists used to obtain these resist patterns which may have superior sensitivity and resolution as compared to materials compared to, e.g., excimer lasers.

However, in order to obtain resist patterns with a line width of 10 nm or less, improvements in both the sensitivity and resolution of chemically amplified resists. Specifically, to address the low EUV absorption rate of organic materials included in chemically amplified resists, the energy of photons emitted by EUV rays should be efficiently converted into chemical reactions.

### SUMMARY

The disclosure provides a radiation-sensitive resist composition having improved absorption properties of radiation (particularly, extreme ultraviolet (EUV) rays) and absorption properties such as improved sensitivity, improved developability, and/or improved resolution, and a pattern formation method using the same.

According to an aspect of the disclosure, there is provided a radiation-sensitive resist which includes an ionic salt (A) comprising an ion (a) and a counter ion (b), the ion (a) comprising a metal chalcogenide cluster structure, and the counter ion (b) having a charge counter to a charge of the ion (a), and a solvent (B), wherein the ion (a) fsubstan comprises a halogen atom and at least one metal atom selected from of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and or Bi.

According to another aspect of the disclosure, there is provided a pattern formation method including applying the radiation-sensitive resist composition onto a substrate to form a resist film, exposing at least a portion of the resist film to radiation, and developing the exposed resist film by using a developer.

### BRIEF DESCRIPTION OF THE DRAWINGS

Embodiments will be more clearly understood from the following detailed description taken in conjunction with the accompanying drawings in which:

FIG. 1A is a graph showing a powder X-ray diffraction analysis pattern of compound 1 obtained in Synthesis Example 1;

FIG. 1B is a graph showing a Fourier transform infrared (FT-IR) spectrum of compound 1 obtained in Synthesis Example 1;

FIG. 2 is a graph showing an FT-IR spectrum of compound 2 obtained in Synthesis Example 2;

FIG. 3 is a graph showing an FT-IR spectrum of compound 3 obtained in Synthesis Example 3;

FIG. 4A is a graph showing a powder X-ray diffraction analysis pattern of compound 4 obtained in Synthesis Example 4;

FIG. 4B is a graph showing an FT-IR spectrum of compound 4 obtained in Synthesis Example 4;

FIG. 5A is a graph showing a powder X-ray diffraction analysis pattern of compound 5 obtained in Synthesis Example 5;

FIG. 5B is a graph showing an FT-IR spectrum of compound 5 obtained in Synthesis Example 5;

FIG. 6A is a view illustrating a chemical structure confirmed by a single crystal X-ray diffraction analysis of compound 6 obtained in Synthesis Example 6;

FIG. 6B is a graph showing an FT-IR spectrum of compound 6 obtained in Synthesis Example 6;

FIG. 7A is a graph showing a powder X-ray diffraction analysis pattern of compound 7 obtained in Synthesis Example 7;

FIG. 7B is a graph showing an FT-IR spectrum of compound 7 obtained in Synthesis Example 7;

FIG. 8 is a flowchart illustrating a pattern formation method according to at least one embodiment;

FIGS. 9A to 9C are side cross-sectional views illustrating a pattern formation method according to at least one embodiment;

FIGS. 10A to 10E are side cross-sectional views illustrating a method of forming a patterning structure, according to at least one embodiment; and

FIGS. 11A to 11E are side cross-sectional views illustrating a method of forming a semiconductor device, according to at least one embodiment.

### DETAILED DESCRIPTION OF THE EMBODIMENTS

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not otherwise be limited by these terms. For example, these terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.” It will be understood that the spatially relative terms are intended to encompass different orientations of the device in use, operation, and/or manufacture, in addition to the orientation depicted in the figures. For example, if the device in one of the figures is turned over, an element or feature described to be “below” another element or feature would then be oriented “above” the other element or feature.

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Unless otherwise stated, operations and measurements of physical properties and the like are performed under conditions of room temperature (20° C. to 25° C.)/relative humidity of 40% RH to 50% RH.

In the description with reference to the drawings, substantially identical or corresponding components are given the same reference numerals, and thus a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Radiation-Sensitive Resist Composition]

A radiation-sensitive resist composition according to at least one embodiment may include an ionic salt (A) and a solvent (B).

### [Ionic Salt (A)]

The ionic salt (A) may include an ion (a), which has a metal chalcogenide cluster structure, and a counter ion (b) of the ion (a). As described in further detail below, the metal chalcogenide cluster may have a metal halide cluster structure including, for example, a halogen atom and at least one metal atom. The at least one metal atom may include for example, one of or more of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi. The ion (a) and the counter ion (b) may be bonded to each other through an ionic bond to form a salt.

The radiation-sensitive resist composition according to at least one embodiment having the above-described configuration may have properties such as improved absorption of radiation (particularly, extreme ultraviolet (EUV) rays), improved sensitivity, improved developability, and improved resolution.

Although not limited to a specific theory, the inventors of the disclosure estimate the following mechanism by which the problem is solved by the radiation-sensitive resist composition according to at least one embodiment.

Since the ion (a), according to at least one example embodiment, includes i) at least one metal atom (e.g., one or more of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi) which may have a relatively high absorption coefficient for radiation (particularly, EUV rays), and ii) a halogen atom which has a higher absorption coefficient for radiation as compared to an oxygen atom and/or a carbon atom, the sensitivity of the radiation-sensitive resist composition according to at least one embodiment may be significantly improved.

In addition, since various structural designs of the counter ion (b) are possible, the sensitivity, developability, resolution, and the like of the ionic salt (A) may be easily improved and/or adjusted.

In addition, since the ionic salt (A) is ionic, a repulsive force between the ions (a) may be improved, thereby improving dispersibility in a solution.

In addition, the counter ion (b) may have a structure in which chemical reactions such as polarity change reactions, decomposition reactions, and crosslinking reactions efficiently occur due to secondary electrons generated from the ion (a) irradiated with radiation. Therefore, the sensitivity, developability, resolution, and the like of the radiation-sensitive resist composition according to at least one embodiment having the counter ion (b) may be improved.

The radiation-sensitive resist composition of the disclosure may undergo a change in solubility in a developer upon exposure to radiation. The radiation-sensitive resist composition may be a positive resist composition in which an exposed portion is dissolved and removed to form a positive type resist pattern or may be a negative type resist composition in which an unexposed portion is dissolved and removed to form a negative type resist pattern. Specifically, the radiation-sensitive resist composition may be a positive type resist composition.

In addition, the radiation-sensitive resist composition according to at least one embodiment may be for a water development process using water for development treatment when a resist pattern is formed, may be for an alkaline development process using an alkaline developer, or may be for a solvent development process using a developer including an organic solvent (hereinafter also referred to as an organic developer).

In some example embodiments, one type of the ionic salt (A) included in the radiation-sensitive resist composition may be used alone, or two or more types thereof may be used in combination.

<Ion (a)>

The ion (a) may have a metal halide cluster structure. Here, the term “metal chalcogenide cluster” is a group of atoms or molecules, or an aggregate of atoms or molecules, which is formed by bonding a plurality of types of atoms or molecules that constitute a metal chalcogenide. By having such a cluster structure, the ion (a) may become smaller in size, and when the ion (a) is used in a radiation-sensitive resist composition, the resolution of the radiation-sensitive resist composition may be improved.

According to at least one example embodiment, the ion (a) may be comprised of halogen atom and at least one metal atom selected from Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi.

In at least one example embodiment, ion (a) may include a metal atom and a halogen atom, and/or may include a metal atom and/or a halogen atom additionally interacting with a solvent molecule so that the solvent molecule constitutes a portion of a metal halide cluster. In at least one embodiment, the ion (a) may include a metal atom and a halogen atom.

The ion (a) may include at least one metal atom selected from titanium (Ti), chromium (Cr), manganese (Mn), iron (Fe), cobalt (Co), copper (Co), zirconium (Zr), niobium (Nb), molybdenum (Mo), technetium (Te), ruthenium (Ru), rhodium (Rh), palladium (Pd), silver (Ag), cadmium (Cd), antimony (Sb), hafnium (Hf), tantalum (Ta), tungsten (W), rhenium (Re), osmium (Os), iridium (Ir), platinum (Pt), mercury (Hg), lead (Pb), and/or bismuth (Bi). From the viewpoint of further improving absorption properties of radiation (particularly, EUV rays), the ion (a) may include at least one metal atom selected from Cu, Nb, Mo, Ag, Sb, Ta, Hg, Pb, and/or Bi, and more specifically, the ion (a) may be at least one metal atom selected from Cu, Ag, Sb, and/or Bi. In addition, the metal atoms in the ion (a) may be used alone or in combination of two or more of the metal atoms.

In at least one example embodiment, the total number atoms of the metal atoms in the ion (a) may be in a range of 2 to 40, specifically, 2 to 30, and more specifically, 2 to 10. For example, in some example embodiments, the metal atoms may comprise of one or more of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi, and a total number atoms included in the metal atoms may be in a range of 2 to 40, specifically, 2 to 30, and more specifically, 2 to 10. When the above range is satisfied, a size of the ion (a) may be further decreased, and resolution may be further improved.

A valence of the ion (a) may be, for example, in a range of about 2 to about 25, specifically, about 2 to about 10. When the above range is satisfied, the film uniformity of an obtained resist film may be further improved, and sensitivity, developability, resolution, and the like may be further improved.

A molecular weight of the ion (a) may be in a range of about 200 to about 9,000, specifically, about 400 to about 6,000. When the above range is satisfied, the size of the ion (a) may be further decreased, and resolution may be further improved. As used herein, the term “molecular weight” is the sum of atomic weights of atoms constituting an ion or compound.

The ion (a) may be anionic or cationic. One type of the ion (a) constituting the ionic salt (A) according to at least one embodiment may be used alone, or two or more types thereof may be used in combination.

The ion (a) may be at least one of the anions represented by Formulas a-1 and/or a-2 below:

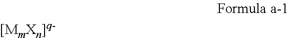

wherein, in Formula a-1,
M may be at least one metal atom selected from Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi,
m may be an integer from 2 to 40,
a plurality of M may be identical to or different from each other,
X may be a halogen atom,
n may be an integer greater than 3 and less than or equal to 60,
a plurality of X may be identical to or different from each other, and
q may be an integer from 2 to 25.

In at least one example embodiment, in Formula a-1, M may be at least one metal of Cu, Nb, Mo, Ag, Sb, Ta, Hg, Pb, and/or Bi; and/or M may be at least one of Cu, Ag, Pb, Sb, and Bi; and/or, M may be at least one of Cu, Ag, Sb, and/or Bi.

In at least one embodiment, in Formula a-1, M may be one to four types, specifically, one or two types, and more specifically, one type.

In at least one example embodiment, in Formula a-1, m may be an integer from 2 to 30, an integer from 2 to 20, an integer from 2 to 10, an integer from 2 to 8, or an integer from 2 to 6.

In some example embodiments, in Formula a-1, X may be a halogen atom selected from F, Cl, Br, and/or I; X may be a halogen atom selected from Cl, Br, and/or I; X may be a halogen atom selected from Br and/or I; and/or particularly, X may be I.

In at least one embodiment, in Formula a-1, X may be one to three types, for example, one or two types, and/or one type.

In at least one example embodiment, in Formula a-1, n may be an integer from 4 to 45, an integer from 6 to 24, an integer from 6 to 18, or an integer from 6 to 10.

In at least one example embodiment, in Formula a-1, q may be an integer from 2 to 12, an integer from 2 to 8, or an integer from 2 to 4.

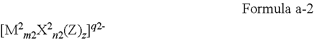

wherein, in Formula a-2,
M² may be at least one of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, and/or Bi,
m² may be an integer from 2 to 40,
a plurality of M² may be identical to or different from each other,
X² may be a halogen atom,
n may be an integer greater than 3 and less than or equal to 60,
a plurality of X² may be identical to or different from each other,
Z may be a solvent molecule,
z may be an integer from 1 to 10,

when z is greater than or equal to 2, a plurality of Z may be identical to or different from each other, and
q2 may be an integer from 2 to 25.

In at least one example embodiment, in Formula a-2, M² may be at least one of Cu, Nb, Mo, Ag, Sb, Ta, Hg, Pb, and/or Bi; M² may be at least one of Cu, Ag, Pb, Sb, and Bi; and/or M² may be at least one of Cu, Ag, Sb, and Bi.

In at least one embodiment, in Formula a-2, M² may be one to four types, one or two types, and/or one type.

In at least one example embodiment, in Formula a-2, m² may be an integer from 2 to 18 or an integer from 2 to 8.

In Formula a-2, X² may be a halogen atom selected from Cl, Br, and I; and/or X² may be I.

In at least one embodiment, in Formula a-2, X² may be one to three types, one or two types, and/or one type.

In at least one example embodiment, in Formula a-2, n2 may be an integer from 4 to 18 or an integer from 6 to 10.

In at least one example embodiment, in Formula a-2, Z may include at least one solvent molecule. For example, the at least one solvent molecule may include one or more of water (H₂O), acetonitrile (MeCN), tetrahydrofuran (THF), dimethylsulfoxide (DMSO), and/or N,N-dimethylformamide (DMF), and/or one or more of water (H₂O), acetonitrile (MeCN), THF, DMSO, and/or N,N-DMF.

In at least one example embodiment, in Formula a-2, z may be an integer from 1 to 6 or an integer from 2 to 4.

In at least one example embodiment, in Formula a-2, q2 may be an integer from 2 to 12, an integer from 2 to 8, or an integer from 2 to 4.

In at least one embodiment, the ion (a) may be at least one of [Cu₆Br₉]³⁻, [Cu₇Br₉]²⁻, [Cu₂I₄]²⁻, [Cu₂I₅]³⁻, [Cu₂I₆]⁴⁻, [Cu₃I₆]³⁻, [Cu₄I₆]²⁻, [Cu₄I₇]³⁻, [Cu₄I₈]⁴⁻, [Cu₅I₇]²⁻, [Cu₆I₉]³⁻, [Cu₆I₁₀]⁴⁻, [Cu₆I₁₂]⁶⁻, [Cu₈I₁₀(MeCN)₂]²⁻, [Cu₈I₁₆]⁸⁻, [Cu₁₁I₁₅]⁴⁻, [Cu₁₃I₂₀]⁷⁻, [Cu₃₆I₆₀]²⁴⁻, [Nb₆Cl₁₈]⁴⁻, [Mo₆Br₁₄]²⁻, [Mo₆I₁₄]²⁻, [Ag₂Cl₄]²⁻, [Ag₂Br₄]²⁻, [Ag₂Br₆]⁴⁻, [Ag₂I₄]²⁻, [Ag₂I₅]³⁻, [Ag₂I₆]⁴⁻, [Ag₃I₆]³⁻, [Ag₄I₈]⁴⁻, [Ag₄I₁₂]⁸⁻, [Ag₆I₁₁]⁵⁻, [Ag₆I₁₂]⁶⁻, [Ag₁₂I₂₄]¹²⁻, [Ag₁₄I₂₂]⁸⁻, [Ag₂₂I₃₄]¹²⁻, [Sb₂Cl₈]²⁻, [Sb₂Cl₁₀]⁴⁻, [Sb₄Cl₁₆]⁴⁻, [Sb₂Br₈]²⁻, [Sb₂I₈]²⁻, [Sb₂I₉]³⁻, [Sb₃I₁₁]²⁻, [Sb₄I₁₆]⁴⁻, [Sb₅I₁₈]³⁻, [Sb₆I₂₂]⁴⁻, [Ta₆Cl₁₈]²⁻, [Hg₂I₆]²⁻, [Hg₄I₁₀]²⁻, [Pb₂I₆]²⁻, [Pb₃I₁₀]⁴⁻, [Pb₃I₁₂]⁶⁻, [Pb₆I₂₂]⁴⁻, [Pb₆I₂₂]¹⁰, [Pb₇I₂₂]⁴⁻, [Pb₇I₂₂]⁸⁻, [Pb₉I₂₆]⁴⁻, [Pb₉I₂₆]⁸⁻, [Pb₁₈I₄₄]⁸⁻, [Bi₂Cl₁₀]⁴⁻, [Bi₂Br₈]²⁻, [Bi₂Br₉]³⁻, [Bi₂Br₁₀]⁴⁻, [Bi₆Br₂₂]⁴⁻, [Bi₈Br₂₈]⁴⁻, [Bi₂I₈]²⁻, [Bi₂I₈(THF)₂]²⁻, [Bi₂I₈(DMSO)₂]²⁻, [Bi₂I₉]³⁻, [Bi₂I₁₀]⁴⁻, [Bi₃I₁₁]²⁻, [Bi₃I₁₂]³⁻, [Bi₄I₁₄]²⁻, [Bi₄I₁₆]⁴⁻, [Bi₅I₁₈]³⁻, [Bi₅I₁₉]⁴⁻, [Bi₆I₂₂]⁴, [Bi₆I₂₄]⁶⁻, [Bi₆I₂₆]⁶⁻, [Bi₆I₂₆]⁸⁻, [Bi₇I₂₄]³⁻, [Bi₈I₂₂]⁴⁻, [Bi₈I₂₈]⁴⁻, [Cu₄Ag₄I₁₂]⁴⁻, and/or [Pb₂Ag₂I₁₀]⁴⁻.

In at least one example embodiment, the ion (a) may be at least one of [Cu₄I₆]²⁻, [Sb₂Cl₈]²⁻, [Sb₂Cl₁₀]⁴⁻, [Sb₂Br₈]²⁻, [Sb₂I₈]²⁻, [Bi₂Cl₁₀]⁴⁻, [Bi₂Br₈]²⁻, [Bi₂I₈]²⁻, and/or [B₁₂I₁₀]⁴⁻.

Representative structures of the metal chalcogenide cluster may include a Keggin structure, a Wells-Dawson structure, and an Anderson-Evans-Perloff structure. Examples of a cluster structure of the ion (a) may include such structures, but the cluster structure of the ion (a) is not limited thereto.

An average diameter of the ion (a) may be in a range of about 0.5 nm to about 10 nm, specifically, about 0.5 nm to about 3 nm, from the viewpoint of further improving resolution. An average diameter may be determined through a method such as single crystal X-ray structural analysis or dynamic light scattering analysis of solutions.

<Counter Ion (b)>

The counter ion (b) may have a structure in which chemical reactions such as polarity change reactions, decomposition reactions, and crosslinking reactions efficiently occur due to secondary electrons generated from the ion (a) irradiated with radiation. The developability, resolution, and the like of the radiation-sensitive resist composition according to at least one embodiment having the counter ion (b) may be improved.

From the viewpoint of further reducing a size of the ionic salt (A) and further improving resolution, a molecular weight of the counter ion (b) may be in a range of about 20 to about 5,000, specifically, about 50 to about 1,000.

In addition, when the counter ion (b) includes carbon atoms, a ratio of the sum of the number of metal atoms contained in the ionic salt (A) to the sum of the number of carbon atoms [sum of the number of metal atoms/sum of the number of carbon atoms] may be in a range of about 0.035 to about 0.200. When the above ratio is 0.200 or less, the solubility of the ionic salt (A) in the solvent (B) may be further improved. When the above ratio is 0.035 or more, the radiation-sensitive resist composition may have further improved absorption properties of radiation (particularly, EUV rays).

In at least one example embodiment, when the ion (a) is an anion, the counter ion (b) may be a cation. For example, the counter ion (b) may include at least one selected from a hydrogen cation (H⁺), a metal cation, a metal complex cation comprising a metal ion and an organic ligand, an ammonium cation, a phosphonium cation, a sulfonium cation, an iodonium cation, a pyridinium cation, an imidazolium cation, a diazonium cation, a guanidinium cation, and/or a hydrazinium cation.

In at least one example embodiment, the metal cation may be at least one selected from an alkali metal cation, an alkaline earth metal cation, and a first transition metal cation, and/or may be an alkali metal cation. The metal cation may be included, for example, as one type, two types, or three or more types.

In at least one example embodiment, the metal complex cation comprising the metal cation and the organic ligand, but may be, for example, a metal complex cation including an organic ligand and a cation of a metal element of Periods 2 to 6 of the periodic table. The metal cation may be, for example, a metal cation of at least one of lithium, sodium, iron, cobalt, nickel, copper, rubidium, yttrium, ruthenium, antimony, cesium, barium, lanthanum, cerium, terbium, platinum, and/or bismuth. In addition, the organic ligand may include, for example, a chemical species having aromaticity and/or a chemical species having heteroatoms (for example, a nitrogen atom, an oxygen atom, a phosphorus atom, and a sulfur atom). The organic ligand may include: for example, aromatic chemical species such as benzene, toluene, and cyclopentadienyl anions; solvent molecules such as water, acetone, acetonitrile, THF, dimethyl sulfoxide, and N,N-dimethylformamide; ethers such as triglyme, tetraglyme, and 18-crown-6-ether; chemical species having a 3-heteroatom-substituted carbonyl structure such as 3-aminopropanolate and acetylacetonate; nitrogen ligands such as ethylenediamine, pyridine, 2,2′-bipyridyl, 1,10-phenanthroline, porphyrin and porphyrinate, and phthalocyanine and phthalocyanate; and/or phosphorus ligands such as triphenylphosphine. The organic ligand may be included as one type, two types, or three or more types.

The ammonium cation may be selected from, for example, a primary ammonium cation having 1 or more carbon atoms, a secondary ammonium cation having 2 or more carbon atoms, a tertiary ammonium cation having 3 or more carbon atoms, and/or a quaternary ammonium cation having 4 or more carbon atoms. For example, the ammonium cation may include at least one of a tertiary ammonium cation having 3 or more carbon atoms and a quaternary ammonium cation having 4 or more carbon atoms. In addition, the ammonium cation may include one or more charged nitrogen atoms in one ion. Furthermore, the ammonium cation may be a cation derived from a nitrogen-containing saturated heterocyclic compound or may be, for example, a cation derived from a compound having a skeleton selected from pyrrolidine, piperidine, piperazine, morpholine, and/or 1,4-diazabicyclo[2.2.2]octane (DABCO).

In addition, the ammonium cation may be represented by Formula 1 below:

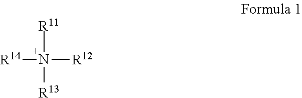

wherein, in Formula 1,
R¹¹ to R¹⁴ may each independently be a hydrogen atom, an alkyl group having 1 to 10 carbon atoms, or an aromatic hydrocarbon group having 6 to 20 carbon atoms, and at least one of R¹¹ to R¹⁴ may not be a hydrogen atom.

The phosphonium cation may be selected from, for example, a primary phosphonium cation having 1 or more carbon atoms, a secondary phosphonium cation having 2 or more carbon atoms, a tertiary phosphonium cation having 3 or more carbon atoms, and/or a quaternary phosphonium cation having 4 or more carbon atoms. For example, the phosphonium cation may include at least one of a tertiary phosphonium cation having 3 or more carbon atoms and/or a quaternary phosphonium cation having 4 or more carbon atoms.

In addition, the phosphonium cation may be represented by Formula 2 below:

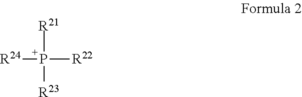

wherein, in Formula 2,
R²¹ to R²⁴ may each independently be a hydrogen atom, an alkyl group having 1 to 10 carbon atoms, or an aromatic hydrocarbon group having 6 to 20 carbon atoms, and at least one of R²¹ to R²⁴ may not be a hydrogen atom.

The sulfonium cation may be selected from, for example, a primary sulfonium cation having 1 or more carbon atoms, a secondary sulfonium cation having 2 or more carbon atoms, and a tertiary sulfonium cation having 3 or more carbon atoms. For example, the sulfonium cation may include a tertiary sulfonium cation having 3 or more carbon atoms.

In addition, the sulfonium cation may be represented by Formula 3 below:

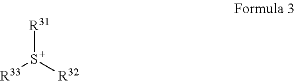

wherein, in Formula 3,
R³¹ to R³³ may each independently be a hydrogen atom, an alkyl group having 1 to 10 carbon atoms, or an aromatic hydrocarbon group having 6 to 20 carbon atoms, and at least one of R³¹ to R³³ may not be a hydrogen atom.

The iodonium cation may have, for example, 2 or more carbon atoms, 6 or more carbon atoms, or 12 or more carbon atoms. The iodonium cation may be, for example, a cation in which an iodine atom is bonded to each of two substituted or unsubstituted aromatic groups, that is, a substituted or unsubstituted diphenyliodonium cation.

The pyridinium cation may or may not have a substituent on a carbon atom and a nitrogen atom which form a nitrogen-containing aromatic ring. In addition, the nitrogen-containing aromatic ring may be a part of a condensed ring structure. The pyridinium cation may be, for example, a cation derived from a compound having a skeleton selected from pyridine, 2,2′-bipyridyl, 4,4′-bipyridyl, quinoline, isoquinoline, and 1,10-phenanthroline.

The imidazolium cation may or may not have a substituent on a carbon atom and a nitrogen atom which form a nitrogen-containing aromatic ring. In addition, the nitrogen-containing aromatic ring may be a part of a condensed ring structure.

The guanidinium cation may be represented by Formula 4 below:

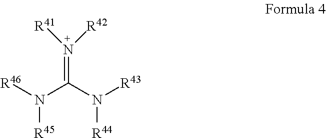

wherein, in Formula 4,
R⁴¹ to R⁴⁶ may each independently be a hydrogen atom, an alkyl group having 1 to 10 carbon atoms, or an aromatic hydrocarbon group having 6 to 20 carbon atoms, and at least one of R⁴¹ to R⁴⁶ may not be a hydrogen atom.

The hydrazinium cation may be represented by Formula 5 below:

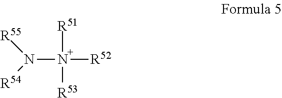

wherein, in Formula 5,
R⁵¹ to R⁵⁵ may each independently be a hydrogen atom, an alkyl group having 1 to 10 carbon atoms, or an aromatic hydrocarbon group having 6 to 20 carbon atoms, and at least one of R⁵¹ to R⁵⁵ may not be a hydrogen atom.

In addition, an upper limit of the carbon number of these ions is not particularly limited, but may be typically 100 or less or 30 or less.

When the counter ion (b) is an ammonium cation or a pyridinium cation, these ions may have at least one functional group selected from a carbon-carbon multiple bond-containing group, a carbonyl group-containing group, an oxime group, an oxime ester group, a halogenated alkyl group, a phosphorus-containing group, a diazo group, and an azide group.

A “carbon-carbon multiple bond-containing group” refers to a group including a double bond or triple bond between two carbon atoms. A double bond includes a conjugated double bond in an aromatic hydrocarbon ring or an aromatic heterocyclic ring.

Examples of the carbon-carbon double bond-containing group may include: ethylenic double bond-containing groups such as a vinyl group, a vinyloxy group, an allyl group, an allyloxy group, a (meth)acryloyl group, a (meth)acryloyloxy group, and a maleimide group; aromatic hydrocarbon ring-containing groups such a phenyl group, a naphthyl group, an anthracenyl group, a benzoic acid group, a cinnamic acid group, an anthraquinone group, a styryl group, a stilbenyl group, a styrylpyridinyl group, and a ketoprofenyl group; aromatic heterocycle-containing groups such as a nicotinic acid group and a thioxanthone group, and groups in which some or all of hydrogen atoms of these groups are substituted with a hydroxyl group, a halogen atom, a monovalent organic group, and the like (hereinafter also referred to as “substituent (x)”); and the like.

Examples of a carbon-carbon triple bond-containing group may include a propargyl group, a propargyloxy group, a group in which some or all of hydrogen atoms of these groups are substituted with a substituent (x), an ethynyl group, an ethynyloxy group, an ethynylcarbonyl group-containing group, a phenylethynylcarbonyl group-containing group, and the like.

A carbonyl group-containing group may be a group including a carbonyl group (>C═O), and examples thereof may include an aldehyde group, a ketone group, a carboxyl group, an alkoxy carbonyl group (ester group), an amide group, an isocyanate group, a carbamate group (—OC(O)NH₂), an acid anhydride residue (—C(O)OC(O)—), an imide residue (—C(O)NHC(O)— or the like), a carbonate group (—OC(O)O—), and the like. More specific examples may include, for example, an acetophenone group, a benzophenone group, a ketoprofen group, and the like.

Examples of the oxime ester group may include oxime methyl ester, oxime ethyl ester, and the like.

Examples of the halogenated alkyl group may include groups in which at least one hydrogen atom of a linear, branched, or cyclic alkyl group having 1 to 10 carbon atoms is replaced with a halogen atom. Examples of a halogen atom included in the halogenated alkyl group may include a fluorine atom, a chlorine atom, a bromine atom, an iodine atom, and the like.

The phosphorus-containing group may be a group including at least one phosphorus atom, and examples thereof may include a phosphonic acid group, a phosphinic acid group, a phosphine oxide group, a phosphonous acid group, a phosphinous acid group, a phosphine group, and the like.

Examples of the diazo group may include a diazoalkane group, a diazonaphthoquinone group, a diaziridine group, and the like.

Examples of the azide group may include an azidomethyl group, an azidoethyl group, an azido aryl group, and the like.

Although it has been described that the ammonium cation and the pyridinium cation of the disclosure may have the above functional group, another counter ion (b) may also have the above functional group.

In at least one embodiment, the counter ion (b) may have at least one functional group selected from a carbon-carbon multiple bond-containing group, a carbonyl group-containing group, an oxime group, an oxime ester group, a halogenated alkyl group, a phosphorus-containing group, a diazo group, and an azide group.

For example, the counter ion (b) may have at least one functional group selected from a vinyl group, a stilbenyl group, an azide group, a diazoalkane group, a diaziridine group, a cinnamic acid group, an anthracenyl group, an anthraquinone group, a maleimide group, a styrylpyridinyl group, an arylsulfonium group, an aryliodonium group, and/or a phenyl ester group.

The counter ion (b) of the disclosure may be a monovalent ion or a divalent or higher ion, but may be a monovalent ion from the viewpoint of resolution. In addition, the counter ion (b) of the disclosure may be anionic or cationic. Furthermore, one type of the counter ion (b) constituting the ionic salt (A) included in the radiation-sensitive resist composition according to at least one embodiment may be used alone, or a combination of two or more types thereof may be used in combination.

Specific examples of the counter ion (b) of the disclosure may include the following Example ions.

### Examples of Hydrogen Cation and Metal Cation

a hydrogen cation (H⁺),
a sodium cation,
a potassium cation, and
a cesium cation.

### Examples of Metal Complex Cation

tetrakis(hydrofuran)lithium(I),
(hexakis(μ₂-aqua)-dodecakis(μ₂-dimethylformamide-O,O)-hexasodium,
hexakis(hydrofuran)sodium(I),
ferrocene,
tris-1,10-phenanthroline iron(II),
bis(η⁵-cyclopentadienyl)cobalt(I),
hexakis(dimethylformamide)cobalt(II),
bis(μ₂-chloro)-tetrakis(N-mesityl-N′-(pyrimidin-2-yl)imidazol-2-ylidene-dinikel(ii),
tetrakis(acetonitrile)copper(I),
bis-1,10-phenanthroline copper(I),
bis-1,10-phenanthroline copper(II),
tris(2-methylphenyl)phosphine tris(acetonitrile)copper(I),
tetrakis(μ₂-3-aminopropanolate)-tricopper(II),
(1,1-di(2-pyridyl)ethanol-N,N′,O)copper(II),
tetraphenylarsonium(V),
(18-crown-6)rubidium(I),
acetonitrile(18-crown-6)rubidium(I),
octakis(dimethylsulfoxide)yttrium(III),
octakis(dimethylformamide)yttrium(III),
heptakis(dimethylsulfoxide)yttrium(III),
tris(2,2′-bipyridine)ruthenium(II),
tetraphenylantimony(V),
tetrakis(p-tolyl)antimony(V),
(μ₂-18-crown-6)bis(18-crown-6)dicesium,
tris(μ₂-dimethylsulfoxide)-decakis(dimethylsulfoxide)dibarium(II),
tris(μ₂-dimethylsulfoxide)-aqua-nonakis(dimethylsulfoxide)dibarium(II),
bis(tetraglyme)barium(II),
bis(acetone)-bis(triglyme)barium(II),
octakis(dimethylsulfoxide)lanthanum(III),
octakis(dimethylsulfoxide)cerium(III),
octakis(dimethylsulfoxide)terbium(III),
bis(ethylenediamine)diiodoplatinum(IV),
bis(acetonato-O,O′)-tetrakis(tetrahydroxyfuran)bismuth(III),
tetraphenylbismuth(V), and
phthalocyaninatebismuth(III)

### Examples of Ammonium Cation

methylammonium,
tetramethylammonium,
methyltriethylammonium,
tri-n-butylmethylammonium,
diethylammonium,
tetraethylammonium,
tetrapropylammonium,
tetrabutylammonium,
tetrapentylammonium,
benzyltriethylammonium,
trimethylphenylammonium,
ethyldimethylphenylammonium,
triethylphenylammonium,
triphenylmethylammonium,
tetraphenylammonium,
1,4-bis(tri-n-butylammonium)butane,
N,N,N′,N′-tetramethyl-1,3-bis(4-piperidyl)propane,
4-methylmorpholine-4-ium,
piperazinium,
N-methylpiperazin-1-ium,
1,4-dimethyl 1,4-piperazinium dication,
4,4′-propane-1,3-diyl-piperazinium,
1-(2-aminoethyl)piperazine-1,4-diium,
N-aminoethylpiperazinium,
1,4-diazabicyclo[2.2.2]octane dication,
1,4-dimethyl-1,4-diazabicyclo[2.2.2]octane,
N,N′-diethyl-1,4-diazabicyclo-[2.2.2]octane,
1,4-dibutyl-1,4-diazabicyclo[2.2.2]octane, and
2-(4-azidebenzoyloxy)ethyl-N,N,N-trimethylammonium.

### Examples of Phosphonium Cation

tetraethylphosphonium,
tetrabutylphosphonium,
bis(triphenyl(propan-2-yl)phosphonium,
tetrakis(phenylmethyl)phosphonium,
methyltriphenylphosphonium,
ethyltriphenylphosphonium,
propyltriphenylphosphonium,
isopropyltriphenylphosphonium,
butyltriphenylphosphonium,
isobutyltriphenylphosphonium,
tetraphenylphosphonium, and
tetrakis(p-tolyl)phosphonium.

### Examples of Iodonium Cations

diphenyliodonium.

### Examples of Pyridinium Cation

pyridinium cation,
1-methylpyridin-1-ium,
1-ethyl-4-dimethylaminopyridinium,
4,4′-(ethane-1,2-diyl)bis(1-ethylpyridin-1-ium),
4,4′-(propane-1,3-diyl)dipiperidinium,
1,2-bis(pyridinium)ethane,
N,N′-dimethylpropane-1,3-bis(pyridinium),
1,4-bis(pyridinium)butane,
1,5-bis(pyridinium)pentane,
1,6-bis(pyridinium)hexane,
1,7-bis(pyridinium)heptane,
2,2′-bipyridinium,
4,4′-bipyridinium,
1,1′-diethyl-4,4′-bipyridinium,
4,4′-(propane-1,3-diyl)di(pyridin-1-ium),
1,1′-diisopropyl-4,4′-bipyridinium,
1,1′-dibutyl-4,4′-bipyridinium,
4,4′,4″-(1,3,5-triazine-2,4,6-triyl)tris(1-methylpyridin-1-ium),
N-(n-butyl)-quinolinium,
N-(isopentyl)-quinolinium,
1,5-bis(isoquinoline)pentane,
1,6-bis(isoquinoline)hexane, and
6,7-dihydro-5H-[1,4]diazepino[1,2,3,4-im][1,10]phenanthroline-4,8-diium.

### Examples of Imidazolium Cation

1,4-bis(dimethylimidazolium)butane,
α,α′-di(3-methylimidazol-1-yl)benzene,
1,1-dimethyl-3,3′-methylene-diimidazolium, and
1,1′,1′-(benzene-1,3,5)tris(3-methyl-1H-imidazol-3-ium).

### Specific Examples of Ionic Salt (A)

Specific examples of the ionic salt (A) of the disclosure may include the following compounds.

[Bi₂I₁₀]⁴⁻•4{sodium},
[Bi₂I₉]³⁻•3{(hexakis(μ₂-aqua)-dodecakis(μ₂-dimethylformamide-O,O)-hexasodium},
[Bi₆I₂₂]⁴⁻•4{methylammonium},
[Sb₂I₈]²⁻•2{tetraphenylphosphonium},
[Sb₆I₂₂]⁴⁻•4{triethylbenzylammonium},
[Bi₆I₂₂]⁴⁻•4{triethylbenzylammonium},
[Bi₅I₁₈]³⁻•3{tetraphenylphosphonium},
[Sb₆I₂₂]⁴⁻•2{tris-1,10-phenanthroline iron(II)},
[Sb₆I₂₂]⁴⁻•4 {ferrocene},
[Sb₃I₁₁]²⁻•2{tetrakis(acetonitrile)copper(I)},
[Sb₅I₁₈]³⁻•3{tetramethylammonium},
[Bi₆I₂₂]⁴⁻•4{tetraethylphosphonium},
[Bi₈I₂₈]⁴⁻•4{1-ethyl-4-dimethylaminopyridinium},
[Bi₂Br₁₀]⁴⁻•2{1,4-diazabicyclo[2.2.2]octane dication}([Bi₂Br₁₀]^{4-•}2{H₂DABCO}),
[Cu₁₁I₁₅]⁴⁻•2{bis-1,10-phenanthroline copper(II)},
[Cu₆I₁₀]⁴⁻•2{4,4′-(ethane-1,2-diyl)bis(1-ethylpyridin-1-ium)},
[Cu₂I₆)₂I]⁴⁻•2{1-(2-aminoethyl)piperazine-1,4-diium)},
[Cu₆I₁₂)₂]⁶⁻•3{1,4-dibutyl-1,4-diazabicyclo[2.2.2]octane},
[Cu₇Br₉]²⁻•{N,N′-dimethylpropane-1,3-bis(pyridinium)},
[Cu₈I₁₆]⁸⁻•4{1,4-dimethyl-1,4-diazabicyclo[2.2.2]octane},
[Cu₂I₄]²⁻•2{isopropyltriphenylphosphonium},
[Bi₂Cl₁₀]⁴⁻•2{1,4-diazabicyclo[2.2.2]octane dication}([Bi₂Cl₁₀]^{4-•}2{H₂DABCO}),
[Bi₂I₁₀]⁴⁻•4{diphenyliodonium},
[Bi₂Br₁₀]⁴⁻•4{diphenyliodonium},
[Bi₂Cl₁₀]⁴⁻•2{1,1-dimethyl-3,3′-methylene-diimidazolium},
[Bi₂Br₁₀]⁴⁻•2{1,1-dimethyl-3,3′-methylene-diimidazolium},
[Bi₂I₁₀]⁴⁻•2{1,1-dimethyl-3,3′-methylene-diimidazolium},
[Sb₂I₉]³⁻•3{Cs⁺},
[Bi₆I₂₆]⁶⁻•2{1,4′-bipyridinium monocation}2{1,4′-bipyridinium dication},
[Bi₂I₁₀]⁴⁻•2{1,4′-bipyridinium dication},
[Bi₂Br₁₀]⁴⁻•2{1,4′-bipyridinium dication},
[Nb₆Cl₁₈]⁴⁻•4{K⁺},
[Bi₇I₂₄]³⁻•3{bis(acetonato-O,O′)-tetrakis(tetrahydroxyfuran)bismuth(III)},
[Ag₁₄I₂₂]⁸⁻•2{tris(μ₂-dimethylsulfoxide)-decakis(dimethylsulfoxide)dibarium(II)},
[Ag₆I₁₁]⁵⁻•{tris(μ₂-dimethylsulfoxide)-aqua-
nonakis(dimethylsulfoxide)dibarium(II)}{H₃O⁺},
[Cu₂I₄]²⁻•{bis(tetraglyme)barium(II)},
[Cu₄I₆]²⁻•{bis(acetone)-bis(triglyme)barium(II)},
[Ag₄I₈]⁴⁻•2{bis(tetraglyme)barium(II)},
[CuAg₇I₁₂]⁴⁻•2{bis(tetraglyme)barium(II)},
[Pb₂Ag₂I₁₀]⁴⁻•2{bis(tetraglyme)barium(II)},
[Bi₃I₁₁]²⁻•2{triethylphenylammonium},
[Bi₈I₂₂]⁴⁻•4{tetraphenylphosphonium},
[Bi₃I₁₂]³⁻•3{triphenylmethylammonium},
[Bi₃I₁₂]³⁻•3{tetraphenylphosphonium},
[Bi₄I₁₄(THF)₂]²⁻•2{tetrakis(tetrahydrofuran)lithium},
[Bi₅I₁₉]⁴⁻•4{tetrakis(tetrahydrofuran)lithium},
[Bi₆I₂₂]⁴⁻•4{tetraphenylphosphonium},
[Mo₆Br₁₄]²⁻•2{Cs⁺},
[Mo₆I₁₄]²⁻•2{Cs⁺},
[Sb₄Cl₁₆]⁴⁻•4{tetraethylammonium},
[Sb₂Cl₈]²⁻•2{tetrapropylammonium},
[Sb₂Cl₈]²⁻•2{tetrabutylammonium},
[Sb₆I₂₂]⁴⁻•4{4-methylmorpholine-4-ium},
[Bi₄I₁₆]⁴⁻•4{4-methylmorpholine-4-ium},
[Sb₄I₁₆]⁴⁻•2{1,4-dimethyl 1,4-piperazinium dication},
[Bi₄I₁₆]⁴⁻•2{1,4-dimethyl 1,4-piperazinium dication},
[Sb₂Br₈]²⁻•2{tetraphenylphosphonium},
[Ta₆Cl₁₈]²⁻•2{H⁺},
[Sb₆I₂₂]⁴⁻•4{tris(2-methylphenyl)phosphine tris(acetonitrile)copper(I)},
[Bi₆I₂₂]⁴⁻•4{tris(2-methylphenyl)phosphine tris(acetonitrile)copper(I)},
[Bi₂Br₉]³⁻•3{tetraphenylphosphonium},
[Bi₆Br₂₂]⁴⁻•4{tetraphenylphosphonium},
[Bi₈Br₂₈]⁴⁻•4{tetraphenylphosphonium},
[Bi₈Br₂₈]⁴⁻•4{tetrabutylammonium},
[Bi₂Br₁₀]⁴⁻•4{K⁺},
[Bi₂Br₉]³⁻•₃{Cs⁺},
[Bi₆I₂₄]⁶⁻•2{4,4′,4″-(1,3,5-triazine-2,4,6-triyl)tris(1-methylpyridin-1-ium)},
[Bi₂I₈](Me₂SO)₂]²⁻•2{propyltriphenylphosphonium},
[Bi₂I₈](Me₂SO)₂]²⁻•2{isobutyltriphenylphosphonium},
[Bi₂I₈](Me₂SO)₂]²⁻•2{butyltriphenylphosphonium},
[Hg₂I₆]²⁻•2{methyltriphenylphosphonium},
[Hg₂I₆]²⁻•2{ethyltriphenylphosphonium},
[Hg₂I₆]²⁻•2{propyltriphenylphosphonium},
[Hg₂I₆]²⁻•2{isopropyltriphenylphosphonium},
[Hg₂I₆]²⁻•2{butyltriphenylphosphonium},
[Hg₂I₆]²⁻•2{isobutyltriphenylphosphonium},
[Hg₄I₁₀]²⁻•2{methyltriphenylphosphonium},
[Hg₄I₁₀]²⁻•2{ethyltriphenylphosphonium},
[Hg₄I₁₀]²⁻•2{propyltriphenylphosphonium},
[Hg₄I₁₀]²⁻•2{isopropyltriphenylphosphonium},
[Hg₄I₁₀]²⁻•2{butyltriphenylphosphonium},
[Hg₄I₁₀]²⁻•2{isobutyltriphenylphosphonium},
[Bi₂I₉]³⁻•3{ethyltriphenylphosphonium},
[Bi₃I₁₂]³⁻•3{methyltriphenylphosphonium},
[Bi₃I₁₂]³⁻•3{isopropyltriphenylphosphonium},
[Bi₅I₁₈]³⁻•3{tetraphenylbismuth(V)},
[Bi₂I₈(THF)₂]²⁻•2{tetrakis(p-tolyl)phosphonium},
[Bi₂I₈(THF)₂]²⁻•2{tetraphenylantimony(V)},
[Bi₂I₈(DMSO)₂]²⁻•2{tetrakis(p-tolyl)phosphonium},
[Bi₂I₈]²⁻•2{tetrakis(phenylmethyl)phosphonium},
[Bi₂I₉]³⁻•3{tetramethylammonium},
[Bi₂I₉]³⁻•3{diethylammonium},
[Bi₂I₁₀]⁴⁻•4{2,2′-bipyridinium},
[Pb₂I₆]²⁻•2{tetraphenylphosphonium},
[Bi₃I₁₂]³⁻•3{tetrabutylammonium},
[Bi₃I₁₂]³⁻•3{tri-n-butylmethylammonium},
[Pb₃I₁₀]⁴⁻•2{1,4-bis(tri-n-butylammonium)butane},
[Pb₇I₂₂]⁸⁻•4{1,4-bis(tri-n-butylammonium)butane},
[Pb₉I₂₆]⁸⁻•4{1,4-bis(tri-n-butylammonium)butane},
[Bi₄I₁₆]⁴⁻•4{phthalocyaninatebismuth(III)},
[Bi₅I₁₈]³⁻•3 {tetraphenylphosphonium},
[Sb₆I₂₂]⁴⁻•4{benzyltriethylammonium},
[Bi₆I₂₂]⁴⁻•4{benzyltriethylammonium},
[Bi₅I₁₈]³⁻•3{tetraphenylantimony(V)},
[Bi₄I₁₆]⁴⁻•4{tetraphenylantimony(V)},
[Bi₅I₁₉]⁴⁻•4{tetrakis(hydrofuran)lithium(I)},
[Bi₆I₂₂]⁴⁻•4{tetraphenylphosphonium},
[Bi₆I₂₂]⁴⁻•4{hexakis(hydrofuran)sodium(I)},
[Bi₆I₂₂]⁴⁻•4{tetraethylphosphonium},
[Bi₆I₂₂]⁴⁻•4{ethyldimethylphenylammonium},
[Bi₆I₂₂]⁴⁻•4{benzyltriethylammonium},
[Bi₆I₂₂]⁴⁻•4{tris(2,2′-bipyridine)ruthenium(II)},
[Bi₈I₂₈]⁴⁻•4{tetraphenylphosphonium},
[Pb₁₈I₄₄]⁸⁻•8{tetrabutylammonium},
[Ag₂₂I₃₄]¹²⁻•4{octakis(dimethylsulfoxide)lanthanum(III)},
[Ag₂₂I₃₄]¹²⁻•4{octakis(dimethylsulfoxide)cerium(III)},
[Cu₂I₅]³⁻•{octakis(dimethylsulfoxide)yttrium(III)},
[Cu₄I₇]³⁻•{octakis(dimethylformamide)yttrium(III)},
[Ag₄I₁₂]⁸⁻•4{N-methylpiperazin-1,4-diium},
[Ag₂I₆]⁴⁻•2{N-methylpiperazin-1,4-diium(H₂O)},
[Cu₄I₈]⁴⁻•2{4,4′-(propane-1,3-diyl)di(pyridin-1-ium)},
[Ag₃I₆]³⁻•{octakis(dimethylformamide)yttrium(III)},
[Ag₂I₅]³⁻{octakis(dimethylsulfoxide)yttrium(III)},
[Ag₁₂I₂₄]¹²⁻•4{heptakis(dimethylsulfoxide)yttrium(III)},
[Cu₂I₅]³⁻I⁻{4,4′-(propane-1,3-diyl)dipiperidinium},
[Cu₂I₅]^{3-•}{octakis(dimethylsulfoxide)terbium(III)},
[Cu₂I₆]⁴⁻•2{piperazinium},
[Cu₂I₄]²⁻•{piperazinium},
[Cu₂I₆]⁴⁻•2{6,7-dihydro-5H-[1,4]diazepino[1,2,3,4-im][1,10]phenanthroline-4,8-diium},
[Cu₂I₆]⁴⁻•4{N-(isopentyl)-quinolinium},
[Cu₂I₆]⁴⁻•2{4,4′-bipyridinium},
[Cu₄I₈]⁴⁻•2{N,N,N′,N′-tetramethyl-1,3-bis(4-piperidyl)propane},
[Ag₂I₄]²⁻•{bis(ethylenediamine)diiodoplatinum(IV)},
[Ag₂I₆]⁴⁻•2{1,5-bis(isoquinoline)pentane},
[Cu₄I₈]⁴⁻•2{1,6-bis(isoquinoline)hexane},
[Ag₂I₆]⁴⁻•2{N-aminoethylpiperazinium},
[Ag₂I₆]⁴⁻•2{1,1′-dibutyl-4,4′-bipyridinium},
[Pb₆I₂₂]¹⁰⁻•5{1,1′-dibutyl-4,4′-bipyridinium},
[Ag₂I₆]⁴⁻•2{1,2-bis(pyridinium)ethane},
[Ag₂I₄]²⁻•{1,4-bis(pyridinium)butane},
[Ag₂I₄]²⁻•{1,7-bis(pyridinium)heptane},
[Ag₂I₄]²⁻•{1,1′-diisopropyl-4,4′-bipyridinium},
[Ag₂Br₄]²⁻•{1,4-bis(pyridinium)butane},
[Ag₂Br₄]²⁻•{1,5-bis(pyridinium)pentane},
[Ag₂Br₄]²⁻•{1,1′-diethyl-4,4′-bipyridinium},
[Ag₂Br₄]²⁻•{1,4-bis(dimethylimidazolium)butane},
[Ag₃I₆]³⁻•3{tetrabutylammonium},
[Cu₄I₈]⁴⁻•4{bis(η⁵-cyclopentadienyl)cobalt(I)},
[Cu₃I₆]³⁻•3{bis(η⁵-cyclopentadienyl)cobalt(I)},
[Cu₃I₆]³⁻•3{trimethylphenylammonium},
[Cu₄I₆]²⁻•2{methyltriethylammonium},
[Cu₄I₆]²⁻•{(18-crown-6)rubidium(I)acetonitrile(18-crown-6)rubidium(I)},
[Cu₄I₆]²⁻•2{tetraphenylphosphonium},
[Cu₁₃I₂₀]⁷⁻•7{tetrabutylammonium},
[Cu₆I₉]³⁻•3{tetraphenylammonium},
[Cu₄I₆]²⁻•2{tetraheptylammonium},
[Ag₄I₈]⁴⁻•4{tetrapropylammonium},
[Cu₄I₈]⁴⁻•2{N,N′-diethyl-1,4-diazabicyclo-[2.2.2]octane},
[Ag₄I₈]⁴⁻•4{tetraphenylphosphonium},
[Ag₄I₈]⁴⁻•4{tetraphenylarsonium(V)},
[Ag₂Cl₄]²⁻•4{tetraphenylarsonium(V)},
[Ag₂Br₄]²⁻•4{tetraphenylarsonium(V)},
[Ag₂Cl₄]²⁻•{bis(μ₂-chloro)-tetrakis(N-mesityl-N′-(pyrimidin-2-yl)imidazol-2-ylidene-
dinikel(ii)},
[Ag₂I₄]²⁻•{bis(μ₂-iodine)-tetrakis(N-mesityl-N′-(pyrimidin-2-yl)imidazol-2-ylidene-
dinikel(ii)},
[Cu₄I₈]⁴⁻•4{N-(n-butyl)-quinolinium},
[Cu₄I₈]⁴⁻•2{1,6-bis(pyridinium)hexane},
[Cu₄I₈]⁴⁻•2{α,α′-di(3-methylimidazol-1-yl)benzene},
[Ag₂Br₆]⁴⁻•2{α,α′-di(3-methylimidazol-1-yl)benzene},
[Ag₄I₁₂]⁸⁻•4{piperazinium},
[Cu₅I₇]²⁻•2{tetrapropylammonium},
[Cu₅I₇]²⁻•2{tetrabutylphosphonium},
[Cu₆I₁₀]⁴⁻•2{tetrakis(μ2-3-aminopropanolate)-tricopper(II)},
[Ag₆I₁₂]⁶⁻•6{tetraethylammonium},
[Cu₆I₁₂]⁶⁻•6{tetraethylammonium},
[Ag₆I₁₂]⁶⁻•2{1,1′,1″-(benzene-1,3,5)tris(3-methyl-1H-imidazol-3-ium},
[Pb₃I₁₂]⁶⁻•2{1,1′,1″-(benzene-1,3,5)tris(3-methyl-1H-imidazol-3-ium},
[Bi₂I₉]³⁻•{1,1′,1″-(benzene-1,3,5)tris(3-methyl-1H-imidazol-3-ium},
[Cu₈I₁₀(MeCN)₂]²⁻•{(μ₂-18-crown-6)bis(18-crown-6)dicesium},
[Ag₁₄I₂₂]⁸⁻•4{hexakis(dimethylformamide)cobalt(II)},
[Cu₃₆I₆₀]²⁴⁻•24{pyridinium cation},
[Cu₆Br₉]³⁻•3{methyltriethylammonium},
[Cu₂I₄]²⁻•{(1,1-di(2-pyridyl)ethanol-N,N′,O)copper(II)},
[Sb₂ICl₁₀]⁴⁻•2{1,4-diazabicyclo[2.2.2]octane dication ([Sb₂Cl₁₀]⁴⁻•2{H₂DABCO},
[Bi₂I₈]²⁻•2{tetraphenylphosphonium}, and
[Bi₂I₈]²⁻•2{tetraphenylphosphonium} 2acetonitrile

One type of the ionic salt (A) included in the radiation-sensitive resist composition of the disclosure may be used alone, or two or more types thereof may be used in combination.

The ionic salt (A) of the disclosure may have a total molecular weight of about 250 to about 30,000, specifically, about 400 to about 15,000, from the viewpoint of improving resolution.

In addition, from the viewpoint of radiation absorption and photosensitivity, in the ionic salt (A) of the disclosure, a ratio of the molecular weight of the ion (a) to the total molecular weight of the counter ion (b) [molecular weight of the ion (a)/total molecular weight of the counter ion (b)] may be in a range of about 0.3 to about 30, specifically, about 0.5 to about 10.

The total molecular weight of the counter ion (b) refers to the total molecular weight of all counter ions (b) contained in an ionic salt. For example, five of monovalent counter ions (b) may be bonded to a pentavalent ion (a), and the total molecular weight of the five of monovalent counter ions (b) may be the total molecular weight of the counter ion (b).

A content of the ionic salt (A) in the total solid content of the radiation-sensitive resist composition of the disclosure may be in a range of about 20 mass % to about 100 mass %. When the content of the ionic salt (A) in the total solid content of the radiation-sensitive resist composition is less than 20 mass %, dissolution contrast may be reduced. The content of the ionic salt (A) in the total solid content of the radiation-sensitive resist composition may be in a range of about 50 mass % to about 100 mass %, specifically, about 80 mass % to about 100 mass %.

The content of the ionic salt (A) in the radiation-sensitive resist composition of the disclosure (the total amount of two or more ionic salts (A)) may be in a range of about 0.5 mass % to about 30 mass %, specifically, about 2 mass % to about 20 mass %, with respect of 100 mass % of the total mass of the radiation-sensitive resist composition.

### <Method of Preparing Ionic Salt>

In at least one example embodiment, a method of preparing the ionic salt (A) may include a method of performing a salt exchange reaction by mixing a compound having the ion (a) including a metal chalcogenide cluster and a compound having the counter ion (b). The salt exchange reaction may be easily performed through a known method. In at least one example embodiment, purification may be performed through a purification method, such as filtration, distillation, extraction, washing with water or an organic solvent, crystallization, treatment with an acid, treatment with an alkali, or column chromatography. Such purification methods may be repeated to adjust a concentration of impurities in a composition to a desired range.

The compound having the ion (a) and the compound having the counter ion (b) may be commercially available products or synthetic products. As a method of synthesizing these compounds, methods in the art may be appropriately referred to and employed.

In at least one example embodiment, the compound having the ion (a) and the compound having the counter ion (b) may be purified through the following method. Purification methods may include filtration, distillation, extraction, washing with water or an organic solvent, recrystallization, crystallization, treatment with an acid, treatment with an alkali, purification through column chromatography, and the like, and an appropriate method may be selected therefrom according to the properties of impurities to be removed. Among these purification methods, purification may be performed through filtration, column chromatography, recrystallization, or standardization. Specifically, purification may be performed through recrystallization. Such purification methods may be repeated to adjust a concentration of impurities in a composition to a desired range.

A structure (composition) of the ionic salt (A) of the disclosure may be confirmed by performing Fourier transform infrared (FT-IR) analysis, nuclear magnetic resonance (NMR) analysis, X-ray fluorescence (XRF) analysis, mass spectrometry, ultraviolet (UV) analysis, single crystal X-ray structural analysis, powder X-ray diffraction (PXRD) analysis, liquid chromatography (LC) analysis, size exclusion chromatography (SEC) analysis, thermal analysis, or the like. Details of a confirmation method are as described in Examples.

### [Solvent (B)]

The solvent (B) included in the radiation-sensitive resist composition of the disclosure is not particularly limited as long as the solvent (B) is a solvent selected to dissolve and/or disperse at least the ionic salt (A) and any components that are contained as desired. As the solvent (B), a solvent used when the ionic salt (A) is synthesized may be used. One type of the solvent (B) may be used alone, or two or more types thereof may be used in combination.

The solvent (B) may be an organic solvent, and examples thereof may include an alcohol-based solvent, an ether-based solvent, a ketone-based solvent, an amide-based solvent, an ester-based solvent, a sulfoxide-based solvent, a hydrocarbon-based solvent, and any combination thereof.

More specifically, examples of the alcohol-based solvent may include a monoalcohol-based solvent such as methanol, ethanol, n-propanol, isopropanol (IPA), 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether (PGME), propylene glycol dimethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like.

Examples of the ether-based solvent may include: a dialkyl ether-based solvent such as diethyl ether, dipropyl ether, or dibutyl ether; a cyclic ether-based solvent such as THF or tetrahydropyran; an aromatic ring-containing ether-based solvent such as diphenyl ether or anisole; and the like.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, or methylcyclohexanone; and 2,4-pentanedione, acetonyl acetone, acetophenone; and the like.

Examples of the amide-based solvent may include: a cyclic amide-based solvent such as N,N′-dimethylimidazolidinone or N-methyl-2-pyrrolidone; a chain amide-based solvent such as N-methylformamide, N,N-DMF, N,N-diethylformamide, acetamide, N-methylacetamide, N,N-dimethylacetamide, or N-methylpropionamide; and the like.

Examples of the ester-based solvent may include: an acetate ester-based solvent such as methyl acetate, ethyl acetate, n-propyl acetate, isopropyl acetate, n-butyl acetate (nBA), isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone or 6-valerolactone; a carbonate-based solvent such as dimethyl carbonate, diethyl carbonate, ethylene carbonate, or propylene carbonate; a lactate ester-based solvent such as methyl lactate, ethyl lactate (EL), n-butyl lactate, or n-amyl lactate; glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate; and the like.

Examples of the sulfoxide-based solvent may include dimethyl sulfoxide, diethyl sulfoxide, and the like.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene; and the like.

In at least one example embodiment, the solvent (B) may be selected from an alcohol-based solvent, an amide-based solvent, an ester-based solvent, a sulfoxide-based solvent, and/or any combination thereof.

For example, the solvent (B) may be selected from PGME, propylene glycol monoethyl ether, PGMEA, N-methyl-2-pyrrolidone, N,N-dimethylacetamide, EL, dimethyl sulfoxide, and a combination thereof.

In at least one example embodiment, since the radiation-sensitive resist composition may not substantially include water, the solvent (B) may not substantially include water. Specifically, the radiation-sensitive resist composition may include water in an amount of 3 mass % or less with respect to the total mass of the radiation-sensitive resist composition, and the solvent (B) may include water in an amount of 3 mass % or less with respect to the total mass of the solvent (B).

### <Additional Components>

In addition to the ionic salt (A) and the solvent (B), the radiation-sensitive resist composition of the disclosure may include, for example, any component such as a radiation-sensitive acid generator, a fluorine atom-containing polymer, a surfactant, a crosslinking agent, a leveling agent, a colorant, or a combination thereof.

The surfactant may exhibit an effect of improving applicability, striation, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include, for example, KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

Examples of the crosslinking agent may include, for example, a melamine-based crosslinking agent, a substituted urea-based crosslinking agent, or a polymer-based crosslinking agent, but one or more embodiments are not limited thereto. A crosslinking agent having at least two crosslinking-forming substituents may include, for example, a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, or methoxymethylated thiourea.

The leveling agent may be used to improve the flatness of a coating film during printing (application), and any known leveling agent that is available commercially may be used.

In addition, in the radiation-sensitive resist composition of the disclosure, a silane coupling agent may be used as any component to improve adhesion to a substrate or the like. Examples of the silane coupling agent may include, for example: vinyltrimethoxysilane, vinyltriethoxysilane, vinyltrichlorosilane, or vinyltris(β-methoxyethoxy)silane; a silane compound having a carbon-carbon unsaturated bond such as 3-methacryloxypropyl trimethoxysilane, 3-acryloxypropyl trimethoxysilane, p-styryl trimethoxysilane, 3-methacryloxypropylmethyl dimethoxysilane, or 3-methacryloxypropylmethyl diethoxysilane; or trimethoxy[3-(phenylamino)propyl]silane.

An usage amount of any components may be easily adjusted and appropriately set according to the desired physical properties. In addition, any components may be used alone or in combination of two or more.

A method of preparing the radiation-sensitive resist composition of the disclosure is not particularly limited, and for example, a method of mixing the ionic salt (A) and any component added as needed in the solvent (B). A temperature or time during mixing is not particularly limited. Filtration may be performed after the mixing if necessary.

### [Pattern Formation Method]

A pattern formation method using a radiation-sensitive resist composition of the disclosure is not particularly limited.

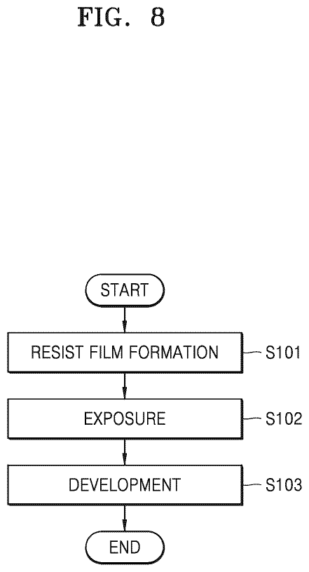

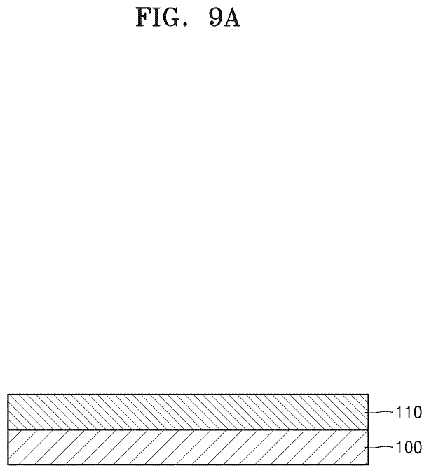

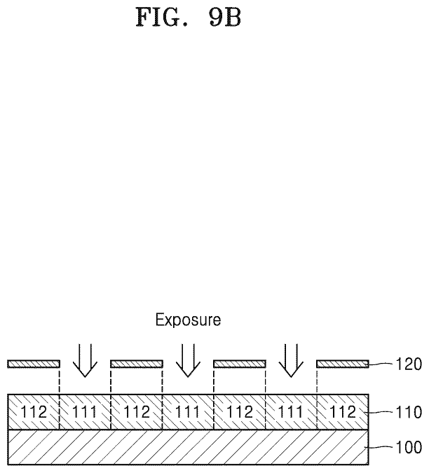

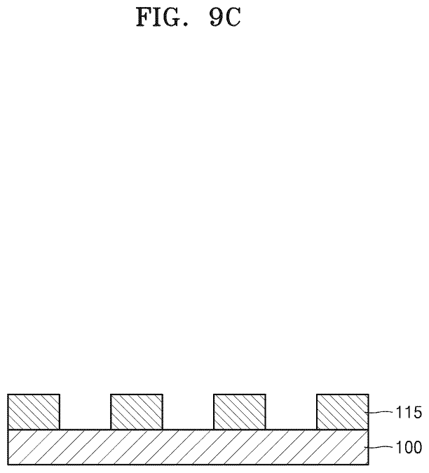

Hereinafter, a pattern formation method according to embodiments will be described in more detail with reference to FIGS. 8 and 9A to 9C. FIG. 8 is a flowchart illustrating the pattern formation method according to embodiments, and FIGS. 9A to 9C are side cross-sectional views illustrating the pattern formation method according to embodiments. Hereinafter, a case in which the radiation-sensitive resist composition is a positive type radiation-sensitive resist composition will be described in detail as an example, but one or more embodiments are not limited thereto.

Referring to FIG. 8, the pattern formation method may include operation S101 of applying a radiation-sensitive resist composition onto a substrate to form a resist film (hereinafter referred to as “application process”), operation S102 of exposing at least a portion of the resist film to radiation through the application process (hereinafter referred to as “exposure process”), and operation S103 of developing the exposed resist film by using a developer (hereinafter referred to as “development process”). Such operations may be omitted if necessary or may be performed in a different order.

Since the pattern formation method uses the radiation-sensitive resist composition according to at least one embodiment, a pattern with high sensitivity, high developability, and high resolution may be formed. Hereinafter, each process will be described.

### <Application Process>

In the present process, a radiation-sensitive resist composition may be applied onto one surface of a substrate 100 to form a resist film 110.

First, the substrate 100 may be prepared. The substrate 100 may include, for example, a semiconductor substrate such as a silicon substrate or a germanium substrate, glass, quartz, ceramic, or copper. In some embodiments, the substrate 100 may include a Group III-V compound such as GaP, GaAs, or GaSb.

The application method may include, for example, spin coating, spray coating, dip coating, knife edge coating, inkjet printing, and screen printing.

After the radiation-sensitive resist composition is applied such that the obtained resist film 110 has a certain thickness, post-application bake (PAB) may be performed as needed, thereby removing a solvent remaining on the resist film 110.

A film thickness of the resist film 110 after the PAB may be in a range of about 1 nm to about 1,000 nm. More specifically, the film thickness of the resist film 110 after the PAB may be 5 nm or more, 10 nm or more, 200 nm or less, or 100 nm or less.

A lower limit of a temperature of the PAB may be 60° C. or more, specifically, 80° C. or more. In addition, an upper limit of the temperature of the PAB may be 150° C. or less, specifically, 140° C. or less. A lower limit of a time of the PAB may be 5 seconds or more, specifically, 10 seconds or more. An upper limit of the time of the PAB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern 115 and converted into a certain pattern. In at least one embodiment, the etching target film may be formed to include, for example, an insulating material such as silicon oxide, silicon nitride, or silicon oxynitride. In some example embodiments, the etching target film may be formed to include a conductive material such as a metal, a metal nitride, a metal silicide, or a metal silicide nitride. In some embodiments, the etching target film may be formed to include a semiconductor material such as polysilicon.

In at least one embodiment, an antireflection film may be further formed on the substrate 100 to maximize the efficiency of a resist. The antireflection film may be an organic or inorganic antireflection film.

In at least one embodiment, a protective film may be further provided on the resist film 110 to reduce the influence of alkaline impurities or the like included during a process. In addition, when immersion exposure is performed, for example, a protective film for immersion may also be installed on the resist film 110 to avoid direct contact between an immersion medium and the resist film 110.

### <Exposure Process>

Next, at least a portion of the resist film 110 may be exposed to radiation. For example, radiation passing through a mask 120 may be irradiated onto at least a portion of the resist film 110. Thus, the resist film 110 may have an exposed portion 111 and an unexposed portion 112.

In some cases, the exposure may be performed by irradiating radiation through a mask with a certain pattern by using an immersion medium such as water. Examples of the radiation may include electromagnetic waves such as visible light, UV rays, deep ultraviolet (DUV) rays, EUV rays (with a wavelength of 13.5 nm), X-rays, and γ-rays; and charged particle beams such as electron beams (EBs) and α-rays. Irradiating the resist film 110 with these radiations may be collectively referred to as “exposure.”

In some example embodiments, radiations that emit a larger amount of secondary electrons from a metal atom included in an ion (a) through exposure may be used, and among such radiations, EUV rays or EBs may be used.

Examples of an exposure light source may include various light sources such as a light source that emits laser light in a UV region, such as a KrF excimer laser (with a wavelength of 248 nm), an ArF excimer laser (with a wavelength of 193 nm), or an F2 excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of radiation, for example, when EUV rays are used as the radiation, the integral dose may be 2,000 mJ/cm² or less, specifically, 500 mJ/cm² or less. In addition, when EBs are used as the radiation, the integral dose may be 5,000 μC/cm² or less, specifically, 1,000 μC/cm² or less.

In addition, post-exposure bake (PEB) may be performed. A lower limit of a temperature of the PEB may be 50° C. or more, specifically, 80° C. or more. An upper limit of the temperature of the PEB may be 180° C. or less, specifically, 130° C. or less. A lower limit of a time of the PEB may be 5 seconds or more, specifically, 10 seconds or more. An upper limit of the time of the PEB may be 600 seconds or less, specifically, 300 seconds or less.

### <Development Process>

Next, the exposed resist film 110 may be developed by using a developer, thereby forming the resist pattern 115. In this case, the exposed portion 111 may be washed away and removed by the developer, and the unexposed portion 112 may remain without being washed away by the developer.

Examples of the developer used in the development may include: water such as pure water or ultrapure water; an alkaline developer; and a developer including an organic solvent (hereinafter referred to as “organic developer”). Examples of a development method may include a dipping method, a puddle method, a spray method, a dynamic injection method, and the like. A development temperature may be, for example, in a range of about 5° C. to about 60° C., and a development time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), 1,5-diazabicyclo[4.3.0]-5-nonene (DBN), and/or the like are dissolved. The alkaline developer may further include a surfactant.

A lower limit of a content of the alkaline compound in the alkaline developer may be 0.1 mass % or more, specifically, 0.5 mass % or more, or more specifically, 1 mass % or more. In addition, an upper limit of the content of the alkaline compound in the alkaline developer may be 20 mass % or less, specifically, 10 mass % or less, or more specifically, 5 mass % or less.

After development, the resist pattern 115 may be washed with ultrapure water, and then the remaining water on the substrate 100 and a pattern may be removed.

For example, the same and/or a substantially similar organic solvent exemplified in the part of [Solvent (B)] of [Resist composition] may be used as the organic solvent included in the organic developer.

For example, n-butyl acetate (nBA), PGME, PGMEA, EL, 7-butyrolactone (GBL), IPA, or the like may be used as the organic developer. The organic developer may further include an organic acid such as an acetic acid, a formic acid, or a citric acid.

A lower limit of a content of the organic solvent in the organic developer may be 80 mass % or more, specifically, 90 mass % or more, more specifically, 95 mass % or more, or particularly, 99 mass % or more.

The organic developer may also include a surfactant. In addition, a trace amount of water may be included in the organic developer. Furthermore, during development, the development may be stopped by substituting the organic developer with a solvent that is a different type therefrom.

The resist pattern 115 after the development may be further washed. Ultrapure water, a rinse solution, or the like may be used as a cleaning solution. A rinse solution is not particularly limited as long as the rinse solution does not dissolve the resist pattern 115, and a solution including a general organic solvent may be used. For example, the rinse solution may be an alcohol-based solvent or an ester-based solvent. After the washing, the rinse solution remaining on the substrate 100 and the pattern may be removed. In addition, when ultrapure water is used, water remaining on the substrate 100 and the pattern may be removed.

In addition, developers may be used alone or in a combination of two or more.

After the resist pattern 115 is formed as described above, a pattern interconnection substrate may be obtained through etching. An etching method may be performed through a known method including dry etching using plasma gas and wet etching using an alkaline solution, a copper (II) chloride solution, an iron (II) chloride solution, or the like.

After the resist pattern 115 is formed, plating may be performed. A plating method is not particularly limited, and examples thereof may include copper plating, solder plating, nickel plating, gold plating, and the like.

The resist pattern 115 remaining after the etching may be peeled off with an organic solvent. One or more embodiments are not limited thereto, but examples of such an organic solvent may include PGMEA, PGME, EL, and the like. A peeling method is not particularly limited, but examples thereof may include an immersion method, a spray method, and the like. In addition, the pattern interconnection substrate on which the resist pattern 115 is formed may be a multi-layer interconnection substrate or may have small-diameter through-holes.

In at least one embodiment, the pattern interconnection substrate may be formed through a method of forming a resist pattern, depositing a metal in a vacuum, and then melting the resist pattern with a solution, that is, a lift-off method.

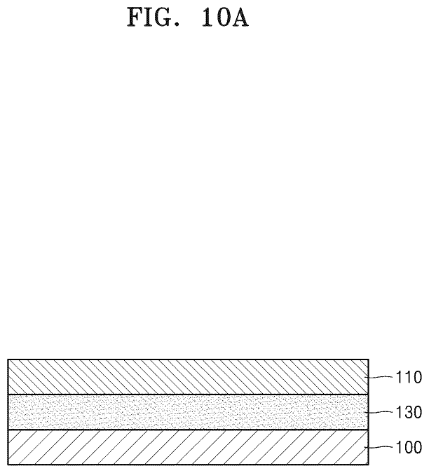

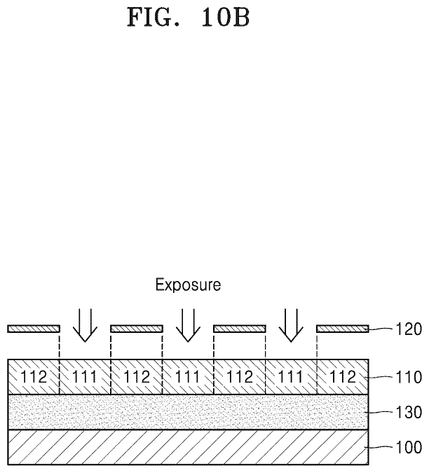

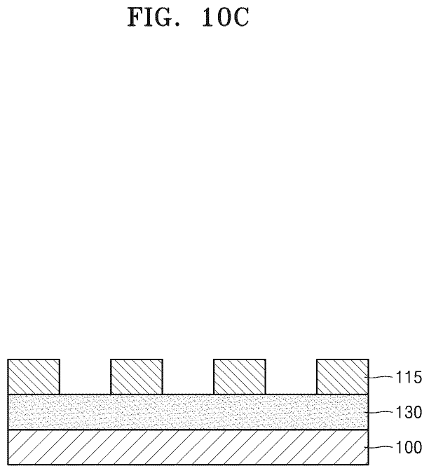

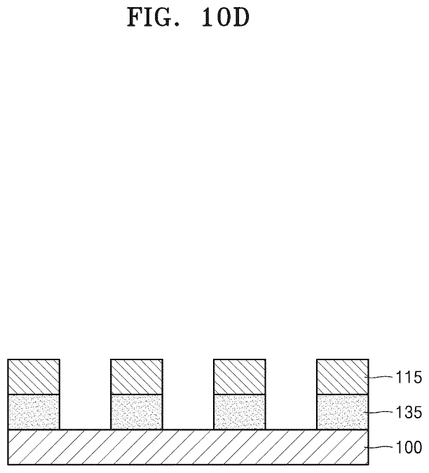

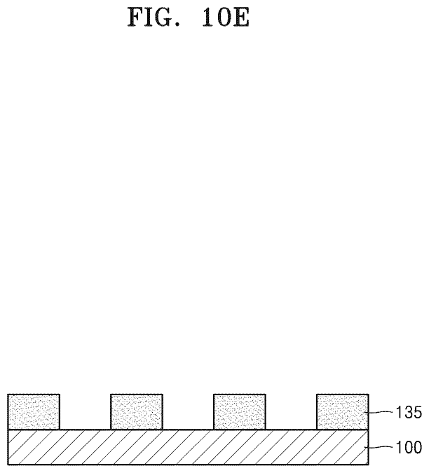

FIGS. 10A to 10E are side cross-sectional views illustrating a method of forming a patterning structure, according to at least one embodiment.

As shown in FIG. 10A, before a resist film 110 is formed on a substrate 100, a material layer 130 may be formed on the substrate 100. The resist film 110 may be formed on the material layer 130. The material layer 130 may include an insulating material (for example, silicon oxide or silicon nitride), a semiconductor material (for example, silicon), or a metal (for example, copper). In some embodiments, the material layer 130 may have a multi-layer structure. A material of the material layer 130 may be different from a material of the substrate 100.

As shown in FIG. 10B, the resist film 110 may be subjected to a pre-exposure bake process and exposed to high-energy rays through a mask 120, and then the resist film 110 may include an exposed portion 111 and an unexposed portion 112.

As shown in FIG. 10C, the exposed resist film 110 may be developed by using a developer (for example, an organic developer). The exposed portion 111 may be washed away by the developer, and the unexposed portion 112 may remain without being washed away by the developer.

As shown in FIG. 10D, an exposed portion of the material layer 130 may be etched by using a resist pattern 115 as a mask to form a material pattern 135 on the substrate 100.

As shown in FIG. 10E, the resist pattern 115 may be removed.

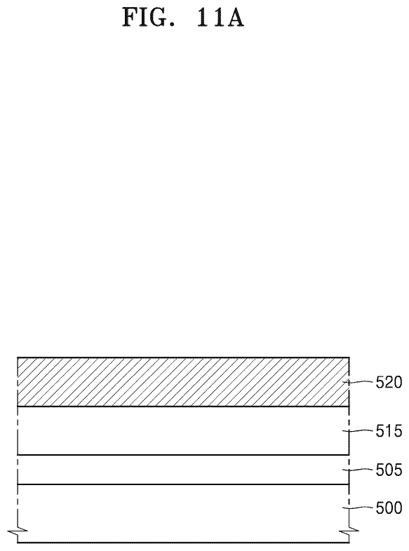

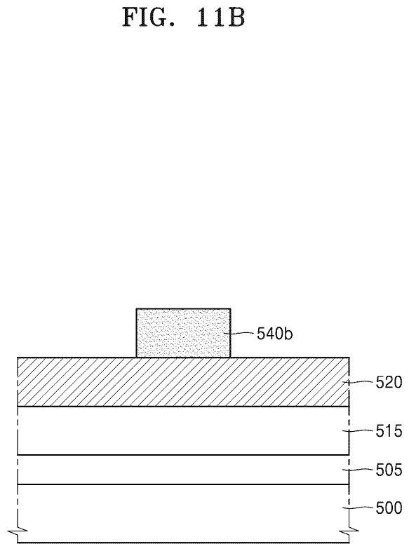

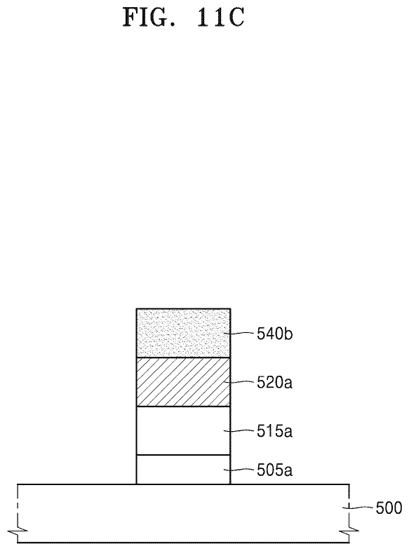

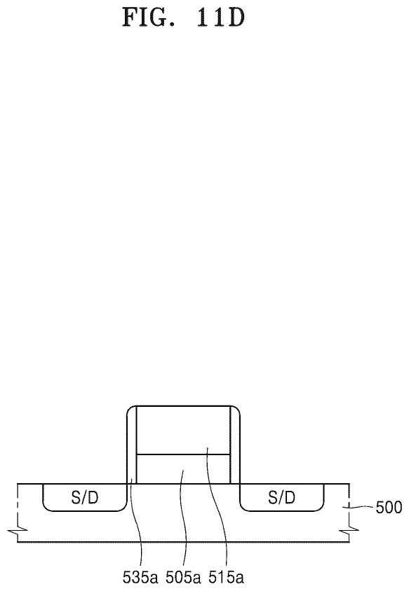

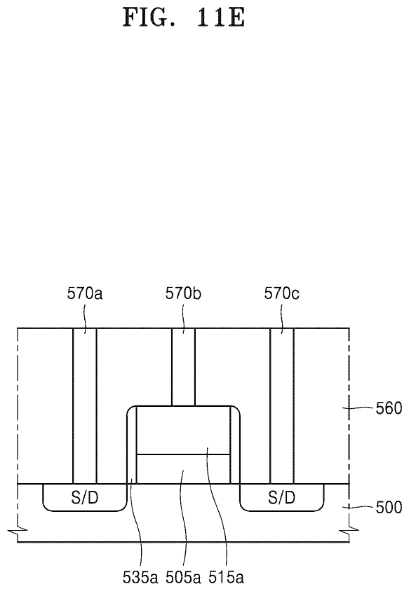

FIGS. 11A to 11E are cross-sectional side views illustrating a method of forming a semiconductor device according to at least one embodiment.

As shown in FIG. 11A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 111B, a resist pattern 540b may be formed on the hardmask layer 520. The resist pattern 540b may be formed by using a resist composition according to at least one embodiment. The resist composition may include an organic solvent.

As shown in FIG. 11C, the gate layer 515 and the gate dielectric 505 may be etched to form a hardmask pattern 520a, a gate electrode pattern 515a, and a gate dielectric pattern 505a.

As shown in FIG. 11D, a spacer layer may be formed on the gate electrode pattern 515a and the gate dielectric pattern 505a. The spacer layer may be formed by using a deposition process (for example, chemical vapor deposition (CVD)). The spacer layer may be etched to form a spacer 535a (for example, silicon nitride) on sidewalls of the gate electrode pattern 515a and the gate dielectric pattern 505a. After the spacer 535a is formed, ions may be implanted into the substrate 500 to form source/drain impurity regions S/D.

As shown in FIG. 11E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal). Although not shown, a barrier layer may be formed between a sidewall of the interlayer insulating film 560 and the electrical contacts 570a, 570b, and 570c.

FIGS. 11A to 11E illustrate an example in which a transistor is formed, but the disclosure is not limited thereto.

The resist composition according to at least one embodiment may be used in a patterning process of forming other types of semiconductor apparatuses.

### [Use]

A radiation-sensitive resist composition according to at least one embodiment may be suitable as a resist composition for KrF excimer laser exposure, a resist composition for ArF excimer laser exposure, a resist composition for EB exposure, or a resist composition for EUV exposure. Specifically, the radiation-sensitive resist composition according to at least one embodiment may be a resist composition for EB exposure or a resist composition for EUV exposure, and may be suitably used for fine processing of semiconductors.

The disclosure will be described in more detail by using the following examples and comparative examples, but these are illustrative and exemplary only and are not intended to limit the scope of the disclosure, and the technical scope of the disclosure is not limited only to the following examples.

### EXAMPLES

### [Analysis Method]

### (Powder X-Ray Diffraction Analysis)

Powder X-ray diffraction analysis was performed by using an X-ray diffractometer (SmartLab manufactured by Rigaku Corporation, X-ray source: CuKα, output: 45 kV-200 mA).

### (Single Crystal X-Ray Diffraction Analysis)

Single crystal X-ray diffraction analysis was performed by using an X-ray diffractometer (Saturn manufactured by Rigaku Co., Ltd., detector: HyPix-6000, X-ray source: MoKα, output: 50 kV-70 mA).

### (FT-IR Spectroscopy Measurement)

An FT-IR spectrum was measured through an attenuated total reflectance (ATR) method using an FT-IR spectrophotometer (Nicolet iS10 manufactured by Thermo Fisher Scientific Inc.).

### Synthesis Example 1

### Compound 1: Synthesis of: [Sb₂Cl₈]²⁻·2{tetrabutylammonium}

Compound 1 was synthesized through improvement of a synthesis method described in the paper by U. Ensinger et al., “Tetraalkylammonium-tetrachloroantimonate(III). Struktur und Schwingungsspektren/Tetraalkylammonium Tetrachloroantimonates(III). Structure and Vibrational Spectra,” Zeitschrift fur Naturforschung B: Chemical Sciences, 1982, 37, 1584. Specifically, 1.23 g (5.40 mmol) of SbCl₃ (manufactured by FUJIFILM Wako Pure Chemical Corporation) and 8.67 g of 1,2-dichloroethane (manufactured by Kanto Chemical Co., Inc.) were put into a glass vial, the glass vial was sealed with a cap, and a solid component was dissolved to prepare solution 1. Next, in another glass vial, 1.50 g (5.40 mmol) of tetrabutylammonium chloride (manufactured by Tokyo Chemical Industry Co., Ltd.) was dissolved in 15.17 g of 1,2-dichloroethane (manufactured by Kanto Chemical Co., Inc.) to prepare solution 2. While solution 2 was stirred, solution 1 was added dropwise thereto. After solution 1 was completely added dropwise, stirring was stopped, and 47.55 g of diethyl ether (manufactured by FUJIFILM Wako Pure Chemical Corporation) was slowly added such that a solution formed two layers. The solution was stored in a refrigerator set at a temperatures of 4° C. for 1 hour to precipitate a white solid. Most of a liquid was removed through decantation, and the remaining liquid was removed by distillation under reduced pressure by using an evaporator. Afterwards, the liquid was removed through vacuum drying to obtain 2.32 g of compound 1 in the form of a white powder.

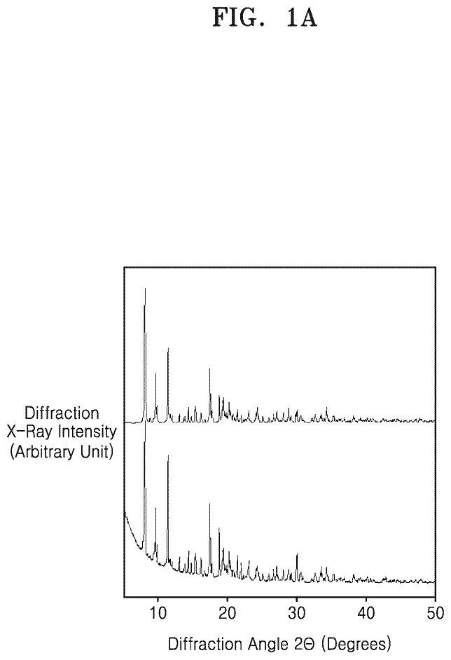

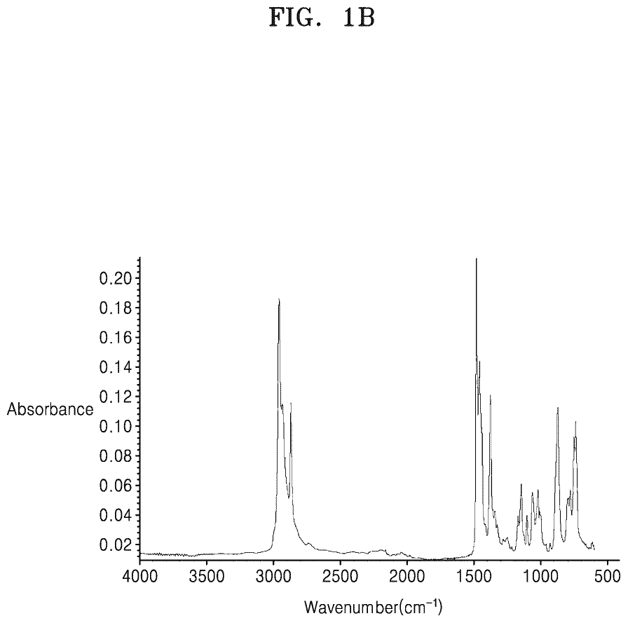

The identification of compound 1 was performed through powder X-ray diffraction analysis. A crystal structure of compound 1 was registered in the Cambridge Structural Database (CSD under CCDC 1113390. A powder X-ray diffraction analysis pattern of compound 1 obtained here through synthesis is shown in the lower part of FIG. 1A, and a powder X-ray diffraction analysis pattern simulated by using crystal structure data reported above is shown in the upper part of FIG. 1A. Since these two patterns were almost identical, it was confirmed that obtained compound 1 was a compound registered under CCDC 1113390.

In addition, the FT-IR spectrum of obtained compound 1 is shown in FIG. 1B.

### Synthesis Example 2

### Synthesis of Compound 2: [Sb₂Cl₁₀]⁴⁻·2{H₂DABCO}·2H₂O

Compound 2 was synthesized through improvement of a synthesis method described in the paper by T. B. Rhaiem et al., “Synthesis, crystal structure, vibrational and optical properties of chlorometalate hybrids incorporating (DABCOH2)²⁺ cations,” Inorganic Chemistry Communications, 2019, 105, 230. Specifically, 0.114 g (0.500 mmol) of SbCl₃ (manufactured by FUJIFILM Wako Pure Chemical Corporation) and 0.056 g (0.500 mmol) of DABCO (manufactured by FUJIFILM Wako Pure Chemical Corporation.,) were dissolved in 80.0 mL (2.0 mmol) of 4 M HCl (manufactured by KISHIDA CHEMICAL Co., Ltd.) in a glass beaker to prepare solution 1. Solution 1 was stored at room temperature for 5 days to evaporate water, and then a transparent crystal was precipitated. Afterwards, an obtained reaction mixture was filtered and separated into a liquid and a solid. Afterwards, the obtained solid was vacuum-dried to obtain 0.091 g of compound 2 in the form of a transparent crystal.

The identification of compound 2 was performed by using an FT-IR spectrum. By comparing the FT-IR spectrum of compound 2 obtained through synthesis with FT-IR spectrum data in the paper, it was confirmed that a target compound was obtained.

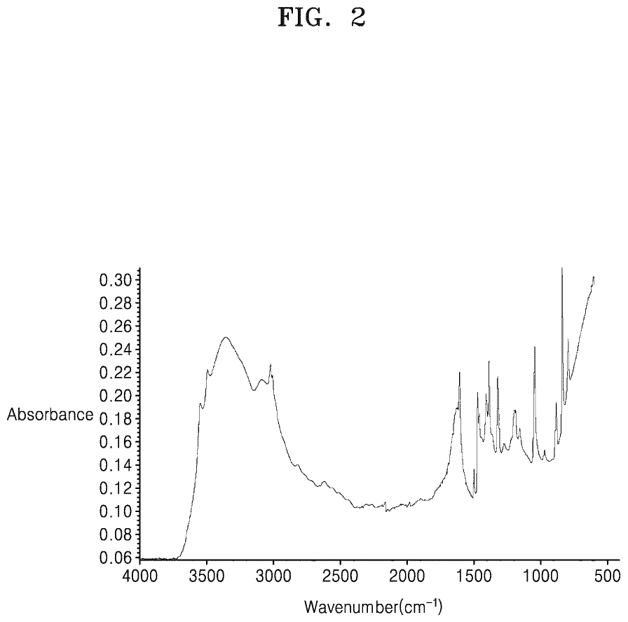

The FT-IR spectrum of obtained compound 2 is shown in FIG. 2.

### Synthesis Example 3

### Compound 3: Synthesis of [Sb₂Br₈]²⁻·2{tetraphenylphosphonium}

Compound 3 was synthesized through improvement of a synthesis method described in the paper by T. Abdulalah et al., “Notizen: Tetraphenylphosphonium-octabromodiantimonat, (PPh₄)₂[Sb₂Br₈]. Synthese und Kristallstruktur/Tetraphenylphosphonium Octabromodiantimonate, (PPh₄)₂[Sb₂Br₈]. Synthesis and Crystal Structure,” Zeitschrift fur Naturforschung B: Chemical Sciences, 2014, 40, 562. Specifically, 0.259 g (0.715 mmol) of SbBr₃ (manufactured by FUJIFILM Wako Pure Chemical Corporation) was dissolved in 249.0 g of dibromomethane (manufactured by FUJIFILM Wako Pure Chemical Corporation) in a glass beaker to prepare solution 1. Next, in another glass beaker, 0.259 g (0.715 mmol) of tetraphenylphosphonium bromide (manufactured by Tokyo Chemical Industry Co., Ltd.) was dissolved in 20.0 g of dibromomethane to prepare solution 2. While solution 2 was stirred, solution 1 was added dropwise thereto. After solution 1 was completely added dropwise, 200.0 g of carbon tetrachloride (manufactured by FUJIFILM Wako Pure Chemical Corporation) was added to obtain a white dispersion. The dispersion was cooled in a refrigerator set at a temperature of 4° C. to precipitate a transparent crystal. Afterwards, an obtained reaction mixture was filtered and separated into a liquid and a solid. Afterwards, the obtained solid was vacuum-dried to obtain 0.910 g of compound 3 in the form of a transparent crystal.

The identification of compound 3 was performed by using an FT-IR spectrum. By comparing the FT-IR spectrum of compound 3 obtained through synthesis with FT-IR spectrum data in the paper, it was confirmed that a target compound was obtained.

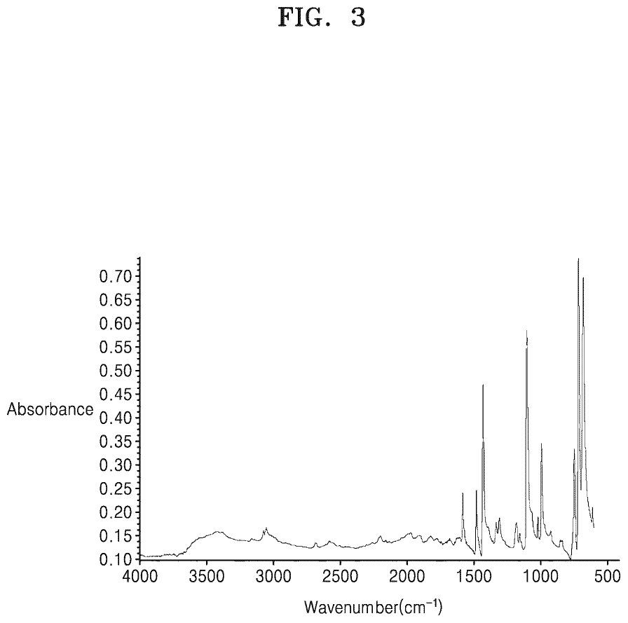

The FT-IR spectrum of obtained compound 3 is shown in FIG. 3.

### Synthesis Example 4

### Compound 4: Synthesis of [Sb₂I₈]²⁻·2{tetraphenylphosphonium}

Compound 4 was synthesized through improvement of a synthesis method described in the paper by E. A. Kovalenko et al., “[Ph₄P]₂[Sb₂I₈]: Weak Interactions between Phenyl Groups of the Cation and Antimony Atoms of the Anion,” Angewandte Chemie International Edition, 1987, 26, 467. Specifically, 0.400 g (0.780 mmol) of SbI₃ (manufactured by Sigma-Aldrich), 0.371 g (0.780 mmol) of tetraphenylphosphonium iodide (manufactured by Tokyo Chemical Industry Co., Ltd.), and 84.4 g of acetonitrile (manufactured by Kanto Chemical Co., Inc.) were put into a glass vial, and the glass vial was sealed with a cap and heated at a temperature of 80° C. After heating for 10 minutes, filtration was performed to remove a solid. A solution obtained through the filtration was distilled under reduced pressure to obtain 0.182 g of compound 4 as an orange powder.

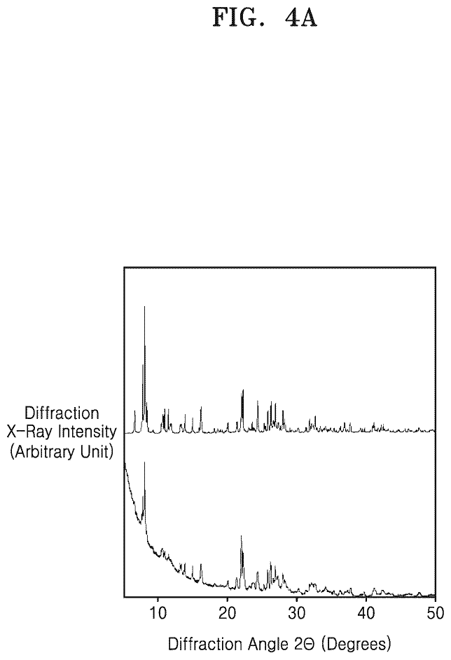

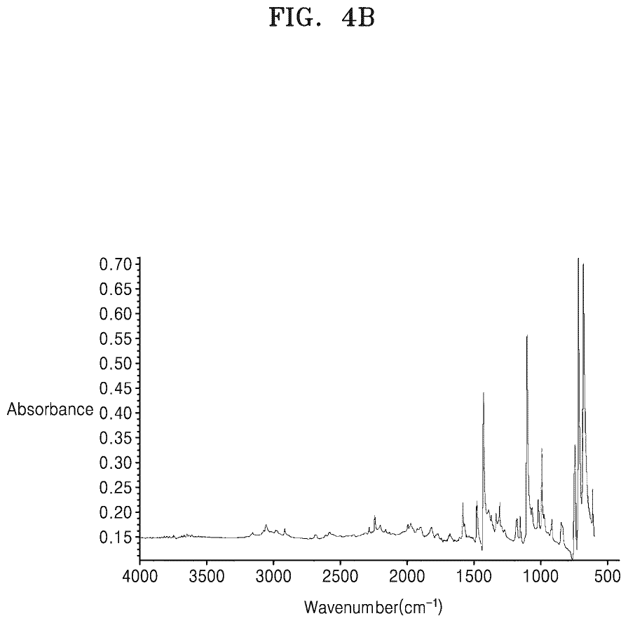

The identification of compound 4 was performed through powder X-ray diffraction analysis. A crystal structure of compound 4 was registered in the CSD under CCDC 1158674. A powder X-ray diffraction analysis pattern of compound 4 obtained here through synthesis is shown in the lower part of FIG. 4A, and a powder X-ray diffraction analysis pattern simulated by using crystal structure data reported above is shown in the upper part of FIG. 4A. Since these two patterns were almost identical, it was confirmed that obtained compound 4 was a compound registered under CCDC 1158674.

In addition, the FT-IR spectrum of obtained compound 4 is shown in FIG. 4B.

### Synthesis Example 5

### Synthesis of Compound 5: [Bi₂Cl₁₀]⁴⁻·2{H₂DABCO}·4H₂O

Compound 5 was synthesized through improvement of a synthesis method described in the paper by E. A. Kovalenko et al., “Crystal Structure of Binuclear Bismuth Complex [H₂dabco]₂[Bi₂Br₁₀]·4H₂O,” J. Struct. Chem., 2018, 59, 193. Specifically, 0.341 g (1.08 mmol) of BiCl₃ (manufactured by Tokyo Chemical Industry Co., Ltd.) and 5.0 mL of 2 M HClaq. (manufactured by FUJIFILM Wako Pure Chemical Corporation) were put into a glass vial, the glass vial was sealed with a cap, and a solid component was dissolved to prepare solution 1. Next, in another vial, 0.200 g (0.625 mmol) of DABCO (manufactured by Fujifilm Wako Pure Chemical Industries, Ltd.) was dissolved in 12.5 mL of 2M HClaq. to prepare solution 2. While solution 2 was stirred, solution 1 was added dropwise thereto to precipitate a white precipitate. After solution 1 was completely added dropwise, an obtained dispersion was filtered and separated into a solution and a solid. The obtained solid was dried through vacuum drying to obtain 0.302 g of compound 5 in the form of a white powder.

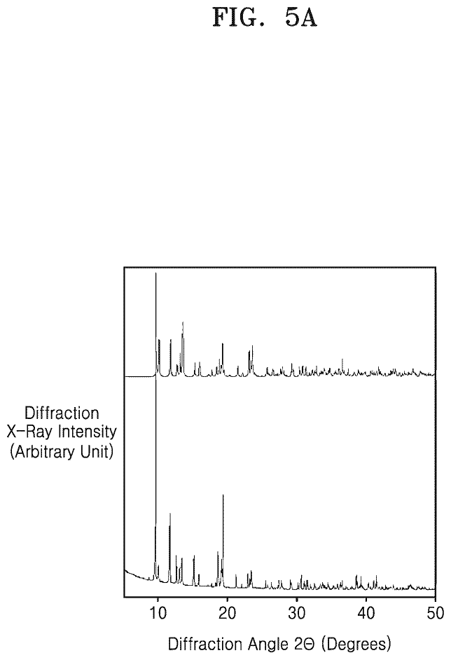

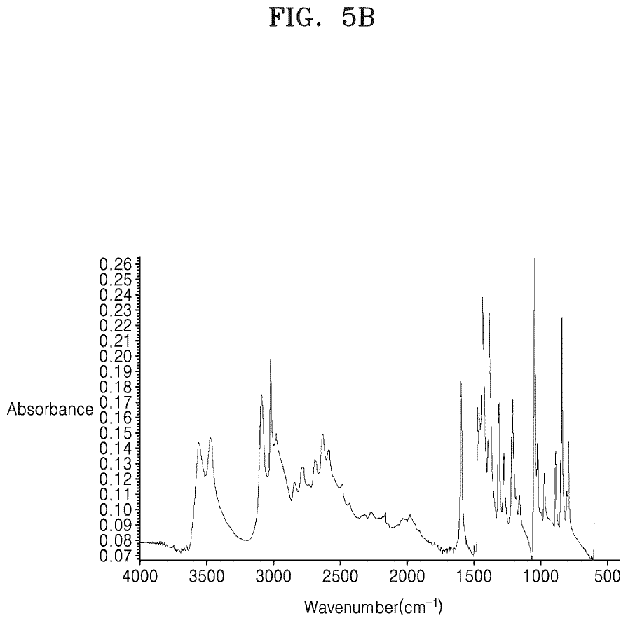

The identification of compound 5 was performed through powder X-ray diffraction analysis. A crystal structure of compound 5 was registered in the CSD under CCDC 1478262. A powder X-ray diffraction analysis pattern of compound 5 obtained here through synthesis is shown in the lower part of FIG. 5A, and a powder X-ray diffraction analysis pattern simulated by using crystal structure data reported above is shown in the upper part of FIG. 5A. Since these two patterns were almost identical, it was confirmed that obtained compound 5 was a compound registered under CCDC 1478262.

In addition, the FT-IR spectrum of obtained compound 5 is shown in FIG. 5B.

### Synthesis Example 6

### Compound 6: Synthesis of [Bi₂I₈]²⁻·2{tetraphenylphosphonium}·2acetonitrile

3.01 g (5.00 mmol) of BiI₃ (manufactured by Tokyo Chemical Industry Co., Ltd.), 1.47 g (3.00 mmol) of tetraphenylphosphonium iodide (manufactured by Tokyo Chemical Industry Co., Ltd.), and 62.9 g of acetonitrile (manufactured by Kanto Chemical Co., Inc.) were put into in a glass vial, the glass vial was sealed with a cap and heated to a temperature of 70° C. After heating for 30 minutes, filtration was performed to remove a solid. A reaction mixture obtained through the filtration was cooled in a refrigerator set at a temperature of 4° C. to obtain 1.52 g of compound 6 in the form of an orange crystal.

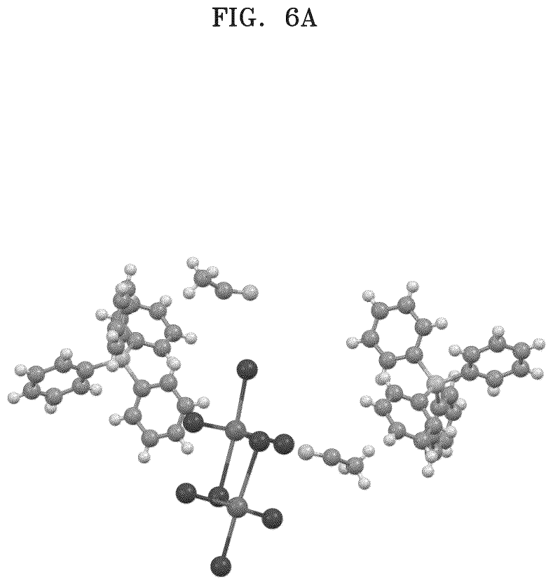

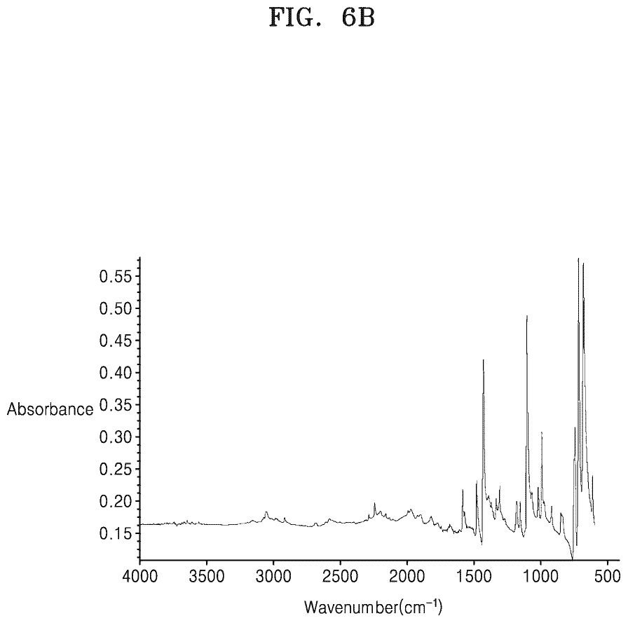

The identification of compound 6 was performed through single crystal X-ray diffraction analysis. The single crystal X-ray diffraction analysis was performed at a temperature of −48° C. by using an X-ray diffractometer. A single crystal was mounted on the X-ray diffractometer and irradiated with Mo Kα rays (λ=0.71073 Å) under a stream of inert gas to measure a diffraction image. Next, by using a set of plane index and diffraction intensity calculated from the diffraction image, a crystal structure was determined through structure determination by a direct method and structure refinement by the least-square method [Acta Cryst. A64, 112 (2008) and A71, 3 (2015)]. As a result of the single crystal X-ray diffraction analysis, it was confirmed that the crystal structure was a crystal of [Bi₂I₈]²⁻·2{tetraphenylphosphonium}·2acetonitrile which had approximate unit cell parameters: a=45.5320 Å; b=13.9977 Å; c=19.9358 Å; α=90°; β=106.119°; γ=90°; V=12206.2 Å³; and Z=8, and in which a space group had C2/c. The chemical structure of obtained compound 6 is shown in FIG. 6A.

The FT-IR spectrum of obtained compound 6 is shown in FIG. 6B.

### Synthesis Example 7

### Compound 7: Synthesis of [Cu₄I₆]²⁻·{bis(acetone)-bis(triglyme)barium(II)}

Compound 7 was synthesized through improvement of a method described in the paper by M. Mishra et al., “Novel Barium-Organic Incorporated Iodometalates: Do They Have Template Properties for Constructing Rare Heterotrimetallic Hybrids?,” Inorganic Chemistry, 2014, 53, 11721. Specifically, 1.16 g (8.00 mmol) of NH₄I (manufactured by FUJIFILM Wako Pure Chemical Corporation) and 2.20 g of dimethyl sulfoxide (manufactured by FUJIFILM Wako Pure Chemical Corporation) were put into a glass vial, the glass vial was sealed with a cap, and a solid component was dissolved to prepare solution 1. Next, 0.78 g (4.04 mmol) of CuI (manufactured by Tokyo Chemical Industry Co., Ltd.), 11.85 g (204.0 mmol) of acetone (manufactured by FUJIFILM Wako Pure Chemical Corporation), and solution 1 were added to another glass vial to obtain solution 2. 0.42 g (0.93 mmol) of BaI₂·2H₂O (manufactured by Sigma-Aldrich), 0.99 g (5.50 mol) of triglyme (manufactured by Sigma-Aldrich), and 5.95 g (102.0 mmol) of acetone (manufactured by FUJIFILM Wako Pure Chemical Corporation) were added to another glass vial to obtain dispersion 1. Solution 2 was added to dispersion 1 and stirred at room temperature for 4 hours, and then a reaction mixture was filtered and separated into a precipitate and a filtrate. Next, a solvent of the obtained filtrate was distilled under reduced pressure at a temperature of 30° C. to obtain a nonvolatile brown solution. 15.8 mg of ethanol (manufactured by FUJIFILM Wako Pure Chemical Corporation) was added to the obtained brown solution to precipitate a yellow precipitate. A solid, which was obtained by filtering a reaction mixture in which the yellow precipitate was formed, was vacuum-dried to obtain 1.45 g of compound 7 as a yellow powder.

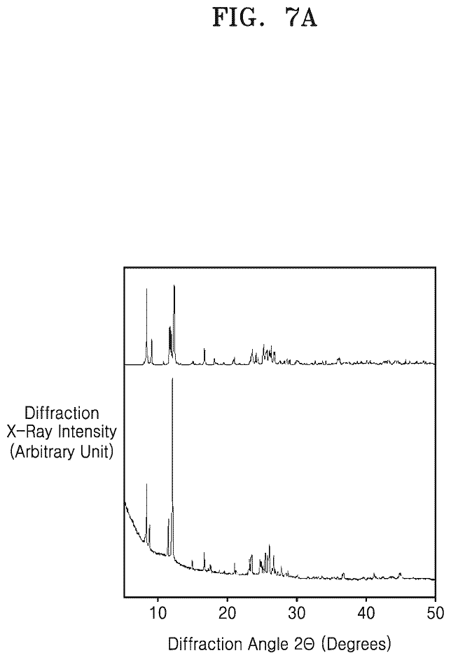

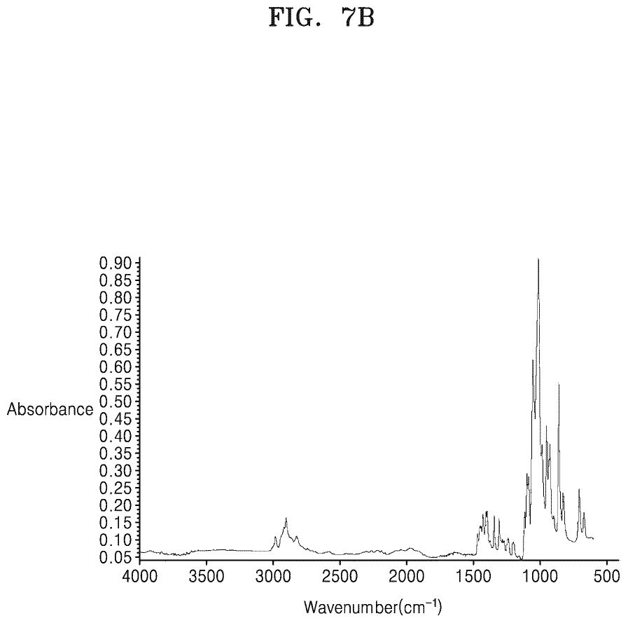

The identification of compound 7 was performed through powder X-ray diffraction analysis. A crystal structure of compound 7 was registered in the CSD under CCDC 1017225. A powder X-ray diffraction analysis pattern of compound 7 obtained here through synthesis is shown in the lower part of FIG. 7A, and a powder X-ray diffraction analysis pattern simulated by using crystal structure data reported above is shown in the upper part of FIG. 7A. Since these two patterns were almost identical, it was confirmed that obtained compound 7 was a compound registered under CCDC 1017225.

In addition, the FT-IR spectrum of the obtained compound 7 is shown in FIG. 7B.

### Comparative Synthesis Example 1

### Synthesis of Comparative Compound 1

Tris(4-bromophenyl)ammoniumyl hexachloroantimonate (manufactured by Sigma-Aldrich) was used without purification.

### Preparation of Resist Composition

0.2 g of each of compounds 1 to 7 and comparative compound 1 was dissolved in 3.8 g of N,N-dimethylacetamide to prepare compositions 1 to 7 and comparative composition 1, respectively.

### [Evaluation]

### (Preparation of Resist Film)

Radiation-sensitive resist compositions 1 to 7 and radiation-sensitive resist comparative composition 1 obtained above were each applied onto a 4-inch silicon wafer by using a spin coater. Afterwards, PAB was performed at a temperature of 90° C. for 60 seconds by using a hot plate to obtain a resist film with a dry film thickness of 50 nm.

### (Exposure of Resist Film to Radiation and Sensitivity Evaluation)

The sensitivity of a radiation-sensitive resist composition was evaluated by irradiating EBs with high sensitivity correlation with EUV rays. By using an electron beam exposure system (ELS-7500 manufactured by Elionix Co., Ltd., acceleration voltage of 50 kV), EBs were irradiated onto two 250 μm×250 μm areas of a resist film at different doses. The doses of the EBs were 500 μC/cm² and 5,000 μC/cm², respectively. After the irradiation, the resist film was developed at a temperature of 25° C. for 1 minute by using a developer shown in Table 1 below and washed with water. After the washing, sensitivity evaluation was performed by measuring a film thickness in two irradiation areas.

When the remaining film was not visually observed in two irradiation areas irradiated with doses of 500 μC/cm² and 5,000 μC/cm², it was marked as ⊚, when no film remained only in the irradiation area irradiated with a dose of 5,000 μC/cm², it was marked as ∘, and when a film remained in both of the two irradiation areas, it was marked as x.

When it is evaluated as ⊚ or ∘, it is considered practical.

Evaluation results are shown in Table 1 below.

TABLE 1

| | Compound | | | | | Evaluation |
|---|---|---|---|---|---|---|
| | | | Anion | Resist | | of |
| | Name | Cation component | component | composition | developer | sensitivity |
| Example 1 | Compound 1 | 2(tetrabutylammonium | [Sb₂Cl₈]²⁻ | Composition 1 | Methanol | ◯ |
| | | cation) | | | | |
| Example 2 | Compound 2 | 2{H₂DABCO}²⁺ | [Sb₂ICl₁₀]⁴⁻ | Composition 2 | Methanol | ◯ |
| Example 3 | Compound 3 | 2(tetraphenylphosphonium | [Sb₂Br₈]²⁻ | Composition 3 | Methanol | ◯ |
| | | cation) | | | | |
| Example 4 | Compound 4 | 2(tetraphenylphosphonium | [Sb₂I₈]²⁻ | Composition 4 | Methanol | ⊚ |
| | | cation) | | | | |
| Example 5 | Compound 5 | 2(H₂DABCO•4H₂O}²⁺ | [Bi₂Cl₁₀]⁴⁻ | Composition 5 | Methanol | ◯ |
| Example 6 | Compound 6 | 2(tetraphenylphosphonium | [Bi₂I₈]² | Composition 6 | Methanol | ⊚ |
| | | cation) | | | | |
| Example 7 | Compound 7 | [Ba(triglyme)₂(acetone)₂]²⁺ | [Cu₄I₆]²⁻ | Composition 7 | Methanol | ◯ |
| Comparative | Comparative | Tris(4- | [SbCl₆]⁻ | Comparative | Methanol | X |
| Example 1 | compound 1 | bromophenyl)ammoniumyl | | composition 1 | | |

From Table 1, compositions 1 to 7 including compounds 1 to 7 exhibited good sensitivity to EBs. On the other hand, comparative composition 1 including comparative compound 1 was evaluated as x and did not obtain sufficient sensitivity even at a dose of 5,000 μC/cm².

### (Comparison of EUV Absorption Coefficients)

The absorption coefficient of [Zr₆O₄(OH)₄]¹²⁺ as a comparison ion and the EUV absorption coefficient of six ions (a) of the disclosure are shown in Table 2 below.

The EUV absorption coefficient of each ion was calculated by using Equation 1. By using the absorption coefficient of each element described in B. L. Henke, E. M. Gullikson, and J. C. Davis. X-ray interactions: photoabsorption, scattering, transmission, and reflection at E=50-30,000 eV, Z=1-92, Atomic Data and Nuclear Data Tables Vol. 54 (no. 2), 181-342 (July 1993), when the absorption coefficient of one carbon atom was set to 1, the EUV absorption coefficient per atom of each ion was calculated from a chemical formula of each ion. In Equation 1, E(x) [unit: g/mol] denotes an atomic weight of a target element, μ(x) [unit: cm²/gm] denotes an atomic absorption coefficient of the target element, and N(x) denotes the number of atoms in an ion of the target element. In addition, E(C) [unit: g/mol] denotes an atomic weight of a carbon element, and μ(C) [unit: cm²/gm] denotes an atomic absorption coefficient of the carbon element, wherein E(C)=12.0110, and μ(C)=2.94.

$$Relative EUV absorption coefficient = \sum \{ E ( x ) \times μ ( x ) \times N ( x ) \} / \sum N ( x ) / \{ E ( c ) \times μ ( c ) \} \qquad Equation 1$$

TABLE 2

| | Relative |
|---|---|
| | EUV |
| | absorption |
| Composition | coefficient |
| [Zr₆O₄(OH)₄]¹²⁺ | 2.1 |
| [Bi₂Cl₁₀]⁴⁻ | 7.0 |
| [Sb₂Br₈]² | 9.4 |
| [Bi₂Br₈]²⁻ | 9.2 |
| [Cu₄I₆]²⁻ | 28.3 |
| [Bi₂I₈]² | 37.9 |
| [Sb₂I₈]²⁻ | 38.1 |

When the EUV absorption coefficients of respective materials were compared with each other, it was confirmed that the EUV absorption coefficients of the six ions (a) of the disclosure were three times or more the absorption coefficient of the comparison ion of [Zr₆O₄(OH)₄]¹²⁺.

While the disclosure has been particularly shown and described with reference to embodiments thereof, it will be understood that various changes in form and details may be made therein without departing from the spirit and scope of the following claims.

What is claimed is:

1. A radiation-sensitive resist composition comprising:
an ionic salt (A) comprising an ion (a) and a counter ion (b), the ion (a) comprising a metal chalcogenide cluster structure, and the counter ion (b) having a charge counter to a charge of the ion (a); and
a solvent (B),
wherein the ion (a) comprises a halogen atom and at least one of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, or Bi.

2. The radiation-sensitive resist composition of claim 1, wherein the ion (a) comprises at least one of Cu, Nb, Mo, Ag, Sb, Ta, Hg, Pb, or Bi.

3. The radiation-sensitive resist composition of claim 1, wherein the ion (a) comprises at least one of Cu, Ag, Sb, or Bi.

4. The radiation-sensitive resist composition of claim 1, wherein a total number of metal atoms in the ion (a) is in a range of 2 to 40.

5. The radiation-sensitive resist composition of claim 1, wherein a valence of the ion (a) is in a range of 2 to 25.

6. The radiation-sensitive resist composition of claim 1, wherein a molecular weight of the ion (a) is in a range of 200 to 9,000.

7. The radiation-sensitive resist composition of claim 1, wherein the ion (a) is at least one selected from anions represented by Formulas a-1 and a-2 below, and
the counter ion (b) is a cation: 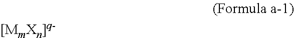
wherein, in Formula a-1,
M is at least one of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, or Bi,
m is an integer from 2 to 40,
a plurality of M are identical to or different from each other,
X is the halogen atom,
n is an integer greater than 3 and less than or equal to 60 and
q is an integer from 2 to 25, and 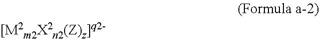
wherein, in Formula a-2,
M² is at least one of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, or Bi,
m2 is an integer from 2 to 40,
a plurality of M² are identical to or different from each other,
X² is the halogen atom,
n is an integer greater than 3 and less than or equal to 60,
a plurality of X² are identical to or different from each other,
Z is a solvent molecule,
z is an integer from 1 to 10, and
q2 is an integer from 2 to 25.

8. The radiation-sensitive resist composition of claim 1, wherein the ion (a) is one or more of [Cu₆Br₉]³⁻, [Cu₇Br₉]²⁻, [Cu₂I₄]²⁻, [Cu₂I₅]³⁻, [Cu₂I₆]⁴⁻, [Cu₃I₆]³⁻, [Cu₄I₆]²⁻, [Cu₄I₇]³⁻, [Cu₄I₈]⁴⁻, [Cu₅I₇]²⁻, [Cu₆I₉]³⁻, [Cu₆I₁₀]⁴⁻, [Cu₆I₁₂]⁶⁻, [Cu₈I₁₀(MeCN)₂]²⁻, [Cu₈I₁₆]⁸⁻, [Cu₁₁I₁₅]⁴⁻, [Cu₁₃I₂₀]⁷⁻, [Cu₃₆I₆₀]²⁴⁻, [Nb₆Cl₁₈]⁴⁻, [Mo₆Br₁₄]²⁻, [Mo₆I₁₄]²⁻, [Ag₂Cl₄]²⁻, [Ag₂Br₄]²⁻, [Ag₂Br₆]⁴⁻, [Ag₂I₄]²⁻, [Ag₂I₅]³⁻, [Ag₂I₆]⁴⁻, [Ag₃I₆]³⁻, [Ag₄I₈]⁴⁻, [Ag₄I₁₂]⁸⁻, [Ag₆I₁₁]⁵⁻, [Ag₆I₁₂]⁶⁻, [Ag₁₂I₂₄]¹²⁻, [Ag₁₄I₂₂]⁸⁻, [Ag₂₂I_{34]12-}, [Sb₂Cl₈]²⁻, [Sb₂Cl₁₀]⁴⁻, [Sb₄Cl_{16]4-}, [Sb₂Br₈]²⁻, [Sb₂I₈]²⁻, [Sb₂I₉]³⁻, [Sb₃I₁₁]²⁻, [Sb₄I₁₆]⁴⁻, [Sb₅I₁₈]³⁻, [Sb₆I₂₂]⁴⁻, [Ta₆Cl₁₈]²⁻, [Hg₂I₆]²⁻, [Hg₄I₁₀]²⁻, [Pb₂I₆]²⁻, [Pb₃I₁₀]⁴⁻, [Pb₃I₁₂]⁶⁻, [Pb₆I₂₂]⁴⁻, [Pb₆I₂₂]¹⁰⁻, [Pb₇I₂₂]⁴⁻, [Pb₇I₂₂]⁸⁻, [Pb₉I₂₆]⁴⁻, [Pb₉I₂₆]⁸⁻, [Pb₁₈I₄₄]⁸⁻, [Bi₂Cl₁₀]⁴⁻, [Bi₂Br₈]²⁻, [Bi₂Br₉]³⁻, [Bi₂Br₁₀]⁴⁻, [Bi₆Br₂₂]⁴⁻, [Bi₈Br₂₈]⁴⁻, [Bi₂I₈]²⁻, [Bi₂I₈(THF)₂]²⁻, [Bi₂I₈(DMSO)₂]²⁻, [Bi₂I₉]³⁻, [Bi₂I₁₀]⁴⁻, [Bi₃I₁₁]²⁻, [Bi₃I₁₂]³⁻, [Bi₄I₁₄]²⁻, [Bi₄I₁₆]⁴⁻, [Bi₅I₁₅]³⁻, [Bi₅I₁₉]⁴⁻, [Bi₆I₂₂]⁴⁻, [Bi₆I₂₄]⁶⁻, [Bi₆I₂₆]⁶⁻, [Bi₆I₂₆]⁸⁻, [Bi₇I₂₄]³⁻, [Bi₈I₂₂]⁴⁻, [Bi₈I₂₈]⁴⁻, [Cu₄Ag₄I₁₂]⁴⁻, or [Pb₂Ag₂I₁₀]⁴⁻.

9. The radiation-sensitive resist composition of claim 1, wherein the ion (a) is one or more of [Cu₄I₆]²⁻, [Sb₂Cl₈]²⁻, [Sb₂Cl₁₀]⁴⁻, [Sb₂Br₈]²⁻, [Sb₂I₈]²⁻, [Bi₂Cl₁₀]⁴⁻, [Bi₂Br₈]²⁻, [Bi₂I₈]²—, or [Bi₂I₁₀]⁴⁻.

10. The radiation-sensitive resist composition of claim 1, wherein
the counter ion (b) comprises carbon atoms, and
a ratio of a total number of metal atoms (M) in the ionic salt (A) to a total number of the carbon atoms (C) in the counter ion (b) [M/C] is in a range of 0.035 to 0.200.

11. The radiation-sensitive resist composition of claim 1, wherein the counter ion (b) comprises at least one of a hydrogen cation (H⁺), a metal cation, a metal complex cation including a metal ion and an organic ligand, an ammonium cation, a phosphonium cation, a sulfonium cation, an iodonium cation, a pyridinium cation, an imidazolium cation, a diazonium cation, a guanidinium cation, or a hydrazinium cation.

12. The radiation-sensitive resist composition of claim 1, wherein a total molecular weight of the ionic salt (A) is in a range of 250 to 30,000.

13. The radiation-sensitive resist composition of claim 1, wherein a content of the ionic salt (A) in the radiation-sensitive resist composition is in a range of about 0.5 mass % to about 30 mass % with respect to 100 mass % of the radiation-sensitive resist composition.

14. The radiation-sensitive resist composition of claim 1, wherein the solvent (B) includes at least one of an alcohol-based solvent, an ether-based solvent, a ketone-based solvent, an amide-based solvent, an ester-based solvent, a sulfoxide-based solvent, a hydrocarbon-based solvent, or a combination thereof.

15. The radiation-sensitive resist composition of claim 1, wherein the solvent (B) is at least one of propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, or a combination thereof.

16. The radiation-sensitive resist composition of claim 1, wherein the solvent (B) includes 3 mass % or less of water with respect to a total mass of the radiation-sensitive resist composition.

17. The radiation-sensitive resist composition of claim 1, wherein the radiation-sensitive resist composition is a positive type radiation-sensitive resist composition.

18. A pattern formation method comprising:
applying a radiation-sensitive resist composition onto a substrate to form a resist film;
exposing at least a portion of the resist film to radiation; and
developing the exposed resist film by using a developer,
wherein the radiation-sensitive resist composition comprises
an ionic salt (A) comprising an ion (a) and a counter ion (b), the ion (a) comprising a metal chalcogenide cluster structure, and the counter ion (b) having a charge counter to a charge of the ion (a), and
a solvent (B), and
the ion (a) comprises a halogen atom and at least one of Ti, Cr, Mn, Fe, Co, Cu, Zr, Nb, Mo, Tc, Ru, Rh, Pd, Ag, Cd, Sb, Hf, Ta, W, Re, Os, Ir, Pt, Hg, Pb, or Bi.

19. The pattern formation method of claim 18, wherein the exposing includes irradiating the resist film with at least of visible light, ultraviolet rays, deep ultraviolet (DUV) rays, extreme ultraviolet (EUV) rays, X-rays, γ-rays, electron beams (EBs), or α-rays.

20. The pattern formation method of claim 18, wherein the exposed resist film comprises an exposed portion and an unexposed portion, and
the developing includes removing the exposed portion.
